(19) United States
(12) Patent Application Publication
(10) Pub. No.: US 2026/0157042 A1
(43) Pub. Date: Jun. 4, 2026

(54) DISPLAY DEVICE, ELECTRONIC DEVICE USING THE SAME AND METHOD FOR PROVIDING THE SAME

(71) Applicant: Samsung Display Co., LTD., Yongin-si (KR)

(72) Inventor: Hyun Eok SHIN, Yongin-si (KR)

(21) Appl. No.: 19/220,515

(22) Filed: May 28, 2025

(30) Foreign Application Priority Data
Dec. 3, 2024 (KR) 10-2024-0177003

(51) Int. Cl. H10K 59/122; H10K 59/12; H10K 77/10; H10K 102/00

(52) U.S. Cl. CPC H10K 59/122; H10K 59/1201; H10K 77/111; H10K 2102/311

(57) ABSTRACT

A display device includes bank structures spaced apart from each other and defining a first light emitting which is between bank structures, a first light emitting element in the first light emitting area and including a first anode electrode, a first light emitting layer and a first cathode electrode, a first pixel defining layer in which a first opening corresponding to the first light emitting area is defined, a second pixel defining layer which overlaps a bank structure among the bank structures and in which a second opening is defined, the second opening defining a second light emitting area overlapping the bank structure, and a second light emitting element in the second light emitting area and overlapping the bank structure, the second light emitting element including a second anode electrode having an edge covered by the second pixel defining layer, a second light emitting layer and a second cathode electrode.

This application claims priority to Korean Patent Application No. 10-2024-0177003 filed on Dec. 3, 2024, and all the benefits accruing therefrom under 35 U.S.C. 119, the contents of which in its entirety are herein incorporated by reference.

### BACKGROUND

### 1. Field

The present disclosure relates to a display device, an electronic device using the same, and a method for fabricating (or providing) the same.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions.

The display device may be a flat panel display device such as a liquid crystal display device, a field emission display device, or an organic light emitting display device. Among the flat panel display devices, the light emitting display device may include a light emitting element in which each of the pixels of a display panel may emit light by itself, thereby displaying an image without a backlight unit providing the light to the display panel.

### SUMMARY

Display devices have been applied to glasses-type devices as examples of an electronic device, to provide virtual reality and augmented reality. In order for the display device to be applied to an electronic device like the glasses-type device, the display device is implemented in a very small size of two inches or less, but should have high pixel integration in order to be implemented with high resolution. For example, the display device may have a high pixel integration of 1500 pixels per inch (PPI) or more.

As described above, when the display device is implemented in a very small size but has high pixel integration, it is difficult to implement light emitting elements separated for each light emitting area using a mask process because an area of a light emitting area where the light emitting elements are disposed is reduced.

Embodiments of the present disclosure provide a display device having a high pixel integration of 1500 pixels per inch (PPI) or more, an electronic device using the same, and a method for fabricating (or providing) the same.

Embodiments of the present disclosure also provide a display device capable of providing an ultra-high-resolution image without reliability defects, an electronic device using the same, and a method for fabricating (or providing) the same.

However, embodiments of the present disclosure are not restricted to those set forth herein. The above and other features of the present disclosure will become more apparent to one of ordinary skill in the art to which the present disclosure pertains by referencing the detailed description of the present disclosure given below.

In an embodiment of the disclosure, a display device including a substrate having cross-repeated planar and tower areas, a first light emitting element including a first anode electrode, a first light emitting layer, and a first cathode electrode positioned on one surface of the substrate, in a portion overlapping the planar area, a first pixel defining layer covering an edge of the first anode electrode and defining a first opening, a bank structure positioned on the first pixel defining layer and having an overhang structure, a second light emitting element including a second anode electrode, a second light emitting layer, and a second cathode electrode positioned on the bank structure, in a portion overlapping the tower area, and a second pixel defining layer covering an edge of the second anode electrode and defining a second opening.

In an embodiment, the first anode electrode and the second anode electrode may be spaced apart from each other with the bank structure interposed therebetween in a direction perpendicular to the one surface of the substrate.

In an embodiment, the planar area is defined by the first opening, the tower area may be defined by the second opening, and in the plan view, an area of the first opening is greater than an area of the second opening.

In an embodiment, the bank structure may include a metal bank layer and an insulating bank layer, and the insulating bank layer includes a tip which protrudes further than a side surface of the metal bank layer.

In an embodiment, the first cathode electrode and the second cathode electrode may be spaced apart from each other with the bank structure interposed therebetween in a direction perpendicular to the one surface of the substrate.

In an embodiment, the side surface of the metal bank layer may include a first side surface in contact with the first cathode electrode, and a second side surface in contact with the second cathode electrode, and the first cathode electrode and the second cathode electrode are electrically connected by the metal bank layer.

In an embodiment, the first light emitting layer may be in contact with the first side surface of the metal bank layer, and the second light emitting layer is not in contact with the metal bank layer.

In an embodiment, the display device may further including a third light emitting element spaced apart from the first light emitting element with the bank structure interposed therebetween and overlapping the planar area, where the first light emitting element and the third light emitting element are positioned on the same line in a direction parallel to the substrate, the second light emitting element is positioned between the first light emitting element and the third light emitting element, and a third cathode electrode included in the third light emitting element is in contact with the second side surface of the metal bank layer.

In an embodiment, the first side surface of the metal bank layer may include a first portion in contact with the first light emitting layer and a second portion in contact with the first cathode electrode, and the second side surface of the metal bank layer includes a first portion in contact with the third cathode electrode and a second portion in contact with the second cathode electrode.

In an embodiment, the first light emitting element, the second light emitting element, and the third light emitting element all emit different colors, in the portion overlapping the planar area, the first light emitting element and the third light emitting element emit at least one of blue light and red light, and in the portion overlapping the tower area, the second light emitting element emits green light.

In an embodiment of the disclosure, a method for fabricating a display device, the method including forming a first anode electrode on a planar area of a substrate and forming a bank structure on a tower area of the substrate, forming a second anode electrode on the bank structure in a portion overlapping the tower area, forming a first light emitting layer and a first cathode electrode on the first anode electrode in a portion overlapping the planar area, and forming a second light emitting layer and a second cathode electrode on the second anode electrode in the portion overlapping the tower area.

In an embodiment, the bank structure includes a metal bank layer including a metal material and an insulating bank layer including an inorganic insulating material, and the insulating bank layer may have a tip which protrudes further than a side surface of the metal bank layer.

In an embodiment, in the forming of the second anode electrode on the bank structure in the portion overlapping the tower area, the second anode electrode may be spaced apart from the first anode electrode with the metal bank layer and the insulating bank layer interposed therebetween in a direction perpendicular to the substrate.

In an embodiment, the first light emitting layer, the first cathode electrode, the second light emitting layer, and the second cathode electrode may be formed by a deposition process and a photo patterning process without using a separate fine metal mask.

In an embodiment of the disclosure, an electronic including at least one display device including a substrate having cross-repeated planar and tower areas, and at least one of a display module, a processor, a memory, and a power module connected to the display device, where the at least one display device includes a first light emitting element including a first anode electrode, a first light emitting layer, and a first cathode electrode positioned on one surface of the substrate, in a portion overlapping the planar area, a first pixel defining layer covering an edge of the first anode electrode and defining a first opening, a bank structure positioned on the first pixel defining layer and having an overhang structure, a second light emitting element including a second anode electrode, a second light emitting layer, and a second cathode electrode positioned on the bank structure, in a portion overlapping the tower area, and a second pixel defining layer covering an edge of the second anode electrode and defining a second opening.

In an embodiment, the first anode electrode and the second anode electrode may be spaced apart from each other with the bank structure interposed therebetween in a direction perpendicular to the one surface of the substrate.

In an embodiment, the planar area may be defined by the first opening, the tower area is defined by the second opening, and in the plan view, an area of the first opening is greater than an area of the second opening.

In an embodiment, the bank structure may include a metal bank layer and an insulating bank layer, and the insulating bank layer includes a tip which protrudes further than a side surface of the metal bank layer.

In an embodiment, the first cathode electrode and the second cathode electrode may be spaced apart from each other with the bank structure interposed therebetween in a direction perpendicular to the one surface of the substrate.

In an embodiment, the side surface of the metal bank layer may include a first side surface in contact with the first cathode electrode, and a second side surface in contact with the second cathode electrode, and the first cathode electrode and the second cathode electrode are electrically connected by the metal bank layer.

According to the display device and the method for fabricating the same according to the embodiments, the display device having the high pixel integration of 1500 pixels per inch (PPI) or more and the method for fabricating the same may be provided.

According to the display device and the method for fabricating the same according to the embodiments, the ultra-high-resolution image without reliability defects may be provided.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other features of the present disclosure will become more apparent by describing in detail embodiments thereof with reference to the attached drawings, in which:

FIG. 1 is a perspective view illustrating a display device according to an embodiment;

FIG. 2 is a cross-sectional view illustrating the display device according to an embodiment;

FIG. 3 is a plan view illustrating a display layer of the display device according to an embodiment;

FIG. 4 is a plan view illustrating a plurality of pixels disposed in a display area in FIG. 3;

FIG. 5 is a cross-sectional view illustrating an example of the display layer taken along line X1-X1′ of FIG. 4;

FIG. 6 is an enlarged cross-sectional view of a display element layer overlapping a first light emitting area included in a planar area in FIG. 5;

FIG. 7 is an enlarged cross-sectional view of a display element layer overlapping a second light emitting area included in a tower area in FIG. 5;

FIG. 8 is a cross-sectional view illustrating an example of the display element layer taken along line X3-X3′ of FIG. 4;

FIG. 9 is a flowchart illustrating a method for fabricating (or providing) the display element layer of FIG. 5;

FIGS. 10 to 12 are cross-sectional views illustrating process S100 of FIG. 9;

FIG. 13 is a cross-sectional view illustrating process S200 of FIG. 9;

FIGS. 14 and 15 are cross-sectional views illustrating process S300 of FIG. 9;

FIGS. 16 to 18 are cross-sectional views illustrating process S400 of FIG. 9;

FIG. 19 is a cross-sectional view illustrating process S500 of FIG. 9;

FIG. 20 is a block diagram of an electronic device according to an embodiment; and

FIG. 21 is a schematic diagram of electronic devices according to various embodiments.

### DETAILED DESCRIPTION

Embodiments of the disclosure now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being related to another element such as being “on” another element, it may be directly on the other element or intervening elements may be therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” may mean within one or more standard deviations, or within ±30%, 20%, 10% or 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments will be described in detail with reference to the accompanying drawings.

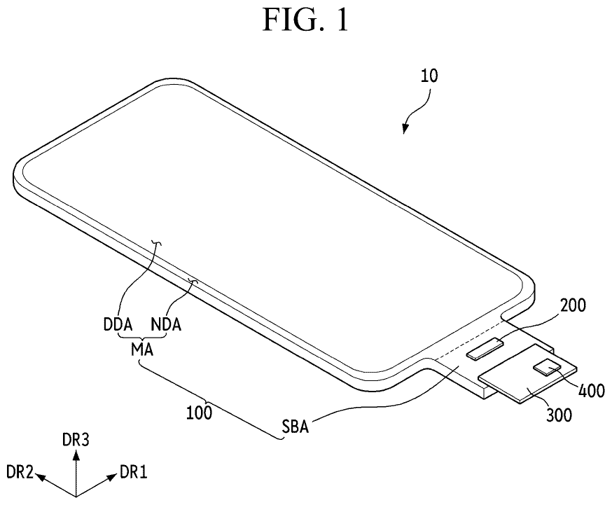

FIG. 1 is a perspective view illustrating a display device 10 according to an embodiment.

Referring to FIG. 1, a display device 10 may be applied to portable electronic devices such as a mobile phone, a smartphone, a tablet personal computer (PC), a mobile communication terminal, an electronic notebook, an electronic book, a portable multimedia player (PMP), navigation, and an ultra-mobile PC (UMPC). For example, the display device 10 may be applied to a display unit of a television, a laptop computer, a monitor, a billboard, or the Internet of Things (IoT). As another example, the display device 10 may be applied to a wearable electronic device such as a smart watch, a watch phone, a glasses-type display, and a head mounted display (HMD).

The display device 10 may be formed (or provided) in a planar shape similar to a quadrangle. For example, the display device 10 may have a planar shape similar to a quadrangle having a short side elongated in a first direction DR1 and a long side elongated in a second direction DR2 crossing the first direction DR1. In a plan view, a corner where the short side in the first direction DR1 and the long side in the second direction DR2 meet each other, may be rounded to have a predetermined curvature or may be formed at a right angle. The planar shape of the display device 10 is not limited to the quadrangle, and may be formed similarly to other polygons, circles, or ovals.

The display device 10 may include a display panel 100, a display driver 200, a circuit board 300, and a touch driver 400.

The display panel 100 may include a main area MA and a sub-area SBA which together may form a total planar area of the display device 10. The main area MA may include a display area DDA including pixels displaying an image, and a non-display area NDA positioned adjacent to the display area DDA, such as being extended around the display area DDA in the plan view.

The display area DDA may emit light from a plurality of light emitting areas or a plurality of openings to be described later. For example, the display panel 100 may include a pixel circuit including switching elements, a pixel defining layer defining the light emitting areas or the openings, and a self-light emitting element connected to the pixel circuit. For example, the self-light emitting element may include, but is not limited to, at least one of an organic light emitting diode (LED) including an organic light emitting layer, a quantum dot LED including a quantum dot light emitting layer, an inorganic LED including an inorganic semiconductor, and a micro LED. In the following drawings, it is illustrated that the self-light emitting element is an organic light emitting diode.

The non-display area NDA may be an area (e.g., a planar area) outside the display area DDA, that is, closer to an outer edge of the display device 10 than the display area DDA. The non-display area NDA may be defined as an edge area of the main area MA of the display panel 100.

The sub-area SBA may be an area extending from one side of the main area MA. The sub-area SBA may include a flexible material in one or more layers of the display device 10 which may be bent, folded, rolled, or the like. For example, when the sub-area SBA is bent, the sub-area SBA may overlap the main area MA in (or along) a thickness direction (e.g., a third direction DR3 which intersects both the first direction DR1 and the second direction DR2, such as being orthogonal thereto). A plane may be defined by the first direction DR1 and the second direction DR2 crossing each other, while a thickness direction may be defined along the third direction DR3. The thickness direction may be perpendicular to the plane defined by the first direction DR1 and the second direction DR2 crossing each other, such as in a direction perpendicular to an underlying layer like the display element layer EML, the substrate SUB, etc.

The sub-area SBA may include the display driver 200 and a pad portion at which the display panel 100 may be connected to the circuit board 300. In another embodiment, the sub-area SBA may be omitted, and the display driver 200 and the pad portion may be positioned in the non-display area NDA. In an embodiment, the sub-area SBA may be a planar area of the overall area of the non-display area NDA, without being limited thereto.

The display driver 200 may output signals and voltages (e.g., electrical signals) for driving the display panel 100. The display driver 200 may be formed (or provided) as an integrated circuit (IC) and mounted on the display panel 100 by a chip on glass (COG) method, a chip on plastic (COP) method, or an ultrasonic bonding method. For example, the display driver 200 may be positioned in the sub-area SBA, and may overlap the main area MA in the thickness direction by the bending of the sub-area SBA. As another example, the display driver 200 may be mounted on the circuit board 300.

The circuit board 300 may be attached onto the pad portion of the display panel 100 using an anisotropic conductive film (ACF). The circuit board 300 may be a flexible film such as a flexible printed circuit board, a printed circuit board, or a chip on film.

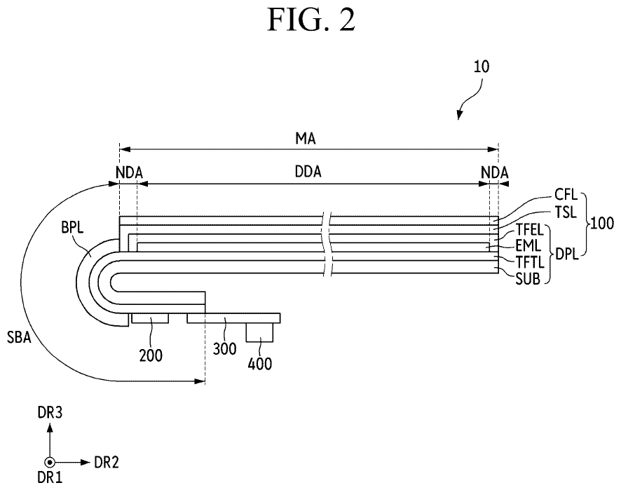

The touch driver 400 may be mounted on the circuit board 300. The touch driver 400 may be connected to a touch sensor layer (TSL in FIG. 2) for sensing a touch and driving a touch sensing function of the display device 10.

FIG. 2 is a cross-sectional view illustrating the display device 10 according to an embodiment.

Referring to FIG. 2, the display panel 100 may include a display layer DPL, a touch sensor layer TSL, and a color filter layer CFL. The display layer DPL may include a substrate SUB, a transistor layer TFTL, a display element layer EML, and a thin film encapsulation layer TFEL.

The substrate SUB may be a base substrate or a base member. The substrate SUB may be a flexible substrate which may be bent, folded, rolled, or the like. For example, the substrate SUB may include a polymer resin such as polyimide (PI), but is not limited thereto. In another embodiment, the substrate SUB may include a glass material or a metal material.

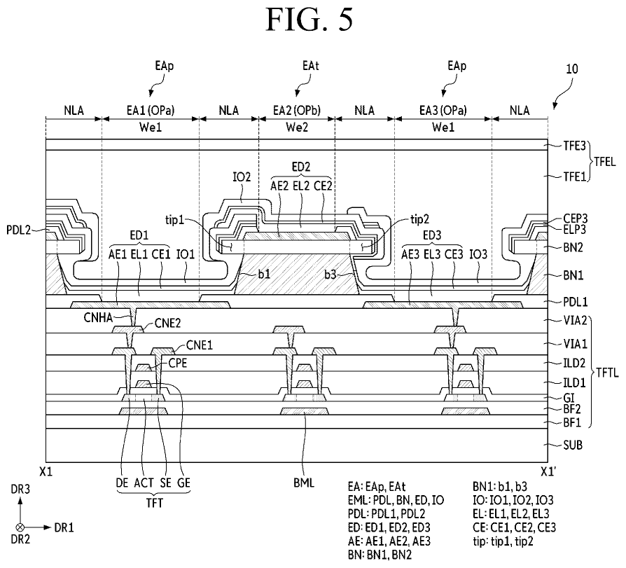

The transistor layer TFTL may be positioned on the substrate SUB. The transistor layer TFTL may be positioned in a portion overlapping the display area DDA, the non-display area NDA, and the sub-area SBA. The transistor layer TFTL may include a plurality of transistors (“TFT” in FIG. 5).

The display element layer EML may be disposed on the transistor layer TFTL. The display element layer EML may be positioned in a portion overlapping the display area DDA. The display element layer EML may include, but is not limited to, at least one of an organic light emitting diode (LED) including an organic light emitting layer, a quantum dot LED including a quantum dot light emitting layer, an inorganic LED including an inorganic semiconductor, and a micro LED. The display element layer EML may be connected (e.g., electrically connected) to the transistor layer TFTL.

The thin film encapsulation layer TFEL as an encapsulation layer may be positioned on the display element layer EML. The thin film encapsulation layer TFEL may be positioned in a portion overlapping the display area DDA and the non-display area NDA. The thin film encapsulation layer TFEL may cover an upper surface and side surfaces of the display element layer EML, and may protect the display element layer EML from oxygen and moisture from the outside. The thin film encapsulation layer TFEL may include at least one inorganic film and at least one organic film for encapsulating the display element layer EML. In some embodiments, the thin film encapsulation layer TFEL may be omitted.

The touch sensor layer TSL may be positioned on the thin film encapsulation layer TFEL. The touch sensor layer TSL may be positioned in a portion overlapping the display area DDA and the non-display area NDA. The touch sensor layer TSL may sense an external input such as a user's touch in a mutual capacitance method or a self-capacitance method. In some embodiments, the touch sensor layer TSL may be omitted.

The color filter layer CFL may be positioned on the touch sensor layer TSL. The color filter layer CFL may be positioned in a portion overlapping the display area DDA and the non-display area NDA. The color filter layer CFL may absorb a portion of light introduced from the outside of the display device 10 to reduce reflected light caused by external light penetrating to a reflective element within the display device 10. Therefore, the color filter layer CFL may prevent color distortion caused by reflection of external light.

As the color filter layer CFL is directly disposed on the touch sensor layer TSL, the display device 10 may not require a separate substrate for the color filter layer CFL. Therefore, the display device 10 may have a relatively small thickness. In some embodiments, the color filter layer CFL may also be omitted.

As illustrated in FIG. 2, a portion of the display panel 100 overlapping the sub-area SBA may be bendable, rollable, foldable and the like. When a portion of the display panel 100 is bent, the display driver 200, circuit board 300, and the touch driver 400 may overlap the main area MA in the third direction DR3.

When a portion of the display panel 100 is bent, a bending protection layer BPL may protect a lower structure (e.g., layers under the bending protection layer BPL) positioned to overlap the sub-area SBA from bending stress.

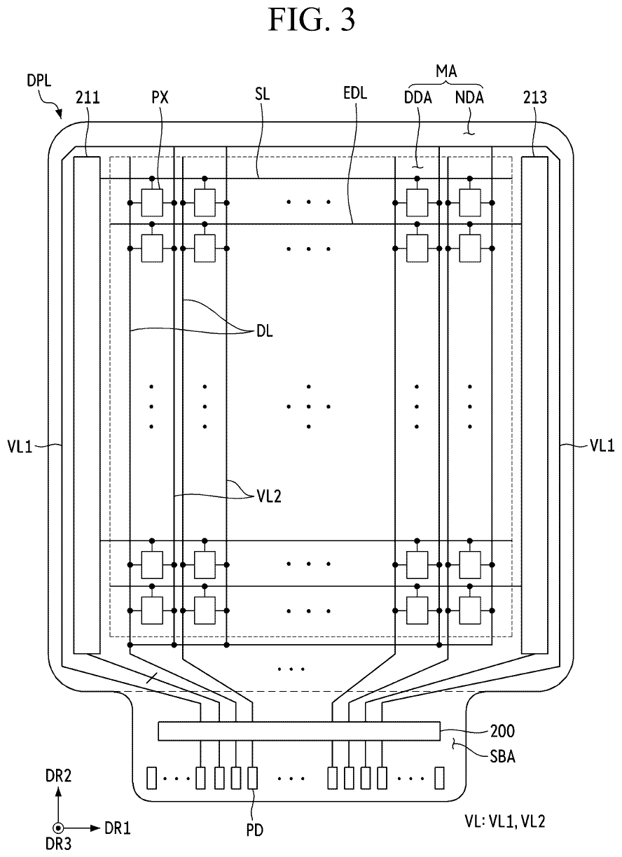

FIG. 3 is a plan view illustrating a display layer DPL of the display device according to an embodiment.

Referring to FIG. 3, the display layer DPL may include a pixel PX provided in plural including a plurality of pixels PX in a portion overlapping the display area DDA, and a plurality of power lines VL, a scan line SL provided in plural including a plurality of scan lines SL, an emission control line EDL provided in plural including a plurality of emission control lines EDL, and a data line DL provided in plural including a plurality of data lines DL, which are variously connected to the plurality of pixels PX. Within the Figures and the text of the disclosure, a reference number indicating a singular form of an element may also be used to reference a plurality of the element.

Each of the plurality of scan lines SL may extend in the first direction DR1 and may be spaced apart from each other in the second direction DR2 which intersects the first direction DR1. The scan lines SL may be arranged along the second direction DR2. The scan lines SL may sequentially supply a scan signal as an electrical signal, to the plurality of pixels PX.

Each of the emission control lines EDL may extend in the first direction DR1 and may be spaced apart from each other in the second direction DR2. The emission control lines EDL may be arranged along the second direction DR2. The emission control lines EDL may sequentially supply a light emitting signal as an electrical signal to the plurality of pixels PX.

The data lines DL may extend in the second direction DR2 and may be spaced apart from each other in the first direction DR1. The data lines DL may be arranged along the first direction DR1. The data lines DL may supply a data voltage as an electrical signal to the plurality of pixels PX. The data voltage may determine luminance of each of the plurality of pixels PX.

The power line VL may include a main power line VL1 and a sub-power line VL2. At least one of a first power voltage (high potential voltage) and a second power voltage (low potential voltage) may be transmitted to the sub-power line VL2 through the main power line VL1 overlapping the non-display area NDA. Hereinafter, the main power line VL1 and the sub-power line VL2 may be collectively referred to as the power line VL.

The non-display area NDA may surround the display area DDA in the plan view. The non-display area NDA may include a scan driver 211 and the emission control driver 213.

The scan driver 211 may be disposed on the outside of one side of the display area DDA or on one side of the non-display area NDA. The scan driver 211 may include a plurality of driving transistors which generate gate signals based on a gate control signal.

The emission control driver 213 may be disposed on the outside of the other side of the display area DDA or on the other side of the non-display area NDA. The emission control driver 213 may include a plurality of emission control transistors which generate light emitting signals based on an emission control signal.

The display layer DPL included in an embodiment may include a display driver 200 and a pad electrode PD provided in plural including a plurality of pad electrodes PD in a portion overlapping the sub-area SBA. The plurality of pad electrodes PD may be positioned to be spaced apart from each other in the first direction DR1, and each pad electrode PD may be connected to each different line among the various signal lines described above.

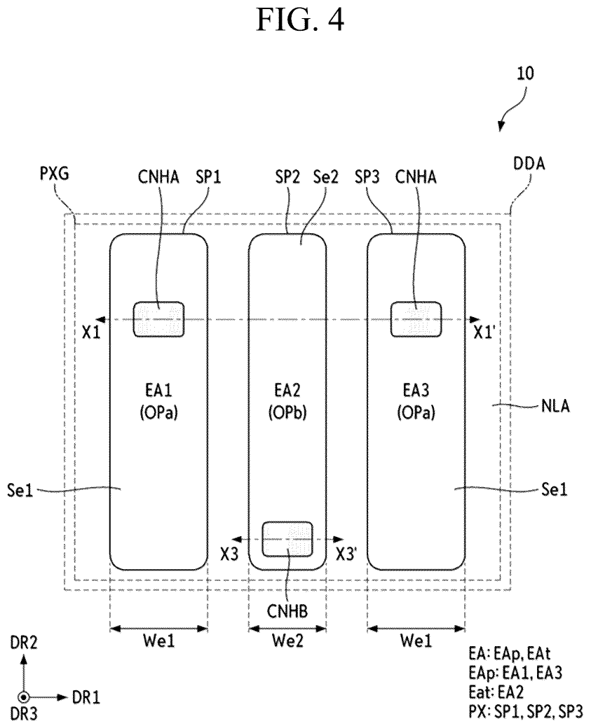

FIG. 4 is a plan view illustrating a plurality of pixels PX disposed in a display area DDA in FIG. 3.

Referring to FIG. 4 in addition to FIGS. 1 to 3, the display device 10 according to an embodiment may include a plurality of pixels PX in a portion overlapping the display area DDA. Each pixel PX among the pixels PX may include a first sub-pixel SP1, a second sub-pixel SP2, and a third sub-pixel SP3. The first sub-pixel SP1, the second sub-pixel SP2, and the third sub-pixel SP3 may be spaced apart from each other within a same one pixel PX.

At least one first sub-pixel SP1, at least one second sub-pixel SP2, and at least one third sub-pixel SP3 disposed to be adjacent to each other may form one pixel group PXG. The pixel group PXG may be a minimum unit which emits light such as white light. However, the type and/or number of pixels PX constituting the pixel group PXG may be variously changed according to the embodiments.

The pixel PX may be positioned in a portion overlapping the light emitting area EA. The light emitting area EA may be an area from which light is emitted.

In an embodiment, the light emitting area EA may include a planar area EAp and a tower area EAt. As an example, the first sub-pixel SP1 and the third sub-pixel SP3 may be positioned in a portion overlapping the planar area EAp, and the second sub-pixel SP2 may be positioned in a portion overlapping the tower area EAt.

In the plan view, the planar area EAp may be defined by a first opening OPa, and the tower area EAt may be defined by a second opening OPb. The first opening OPa and the second opening OPb and the various stacked structures respectively defining such features will be described later.

In a plan view, a first width We1 of the first opening OPa in the first direction DR1 may be greater than a second width We2 of the second opening OPb. In other words, in the plan view, a first area Se1 (e.g., a first planar area) of the first opening OPa defining the planar area EAp may be greater than a second area Se2 (e.g., a second planar area) of the second opening OPb defining the tower area EAt. As an example, it is illustrated in the drawing that lengths of the first opening OPa and the second opening OPb in the second direction DR2 are the same, but the present disclosure is not limited thereto.

The display device 10 according to an embodiment may adjust an area of the light emitting area EA, thereby adjusting the intensity of light emitted from the light emitting area EA and controlling the color of a displayed image at a display screen of the display device 10.

In an embodiment, the first sub-pixel SP1 positioned in the portion overlapping the planar area EAp may include a first light emitting area EA1, the second sub-pixel SP2 positioned in the portion overlapping the tower area EAt may include a second light emitting area EA2, and the third sub-pixel SP3 positioned in the portion overlapping the planar area EAp may include a third light emitting area EA3.

The first light emitting area EA1, the second light emitting area EA2, and third light emitting area EA3 may emit light of different colors. As an example, the first light emitting area EA1 may emit blue light, the second light emitting area EA2 may emit green light, and the third light emitting area EA3 may emit red light. However, the present disclosure is not limited thereto, and in another embodiment, the first light emitting area EA1 may emit red light, the second light emitting area EA2 may emit green light, and the third light emitting area EA3 may emit blue light.

In an embodiment, the first sub-pixel SP1 and the third sub-pixel SP3 may include a planar contact hole CNHA, and, and the second sub-pixel SP2 may include a tower contact hole CNHB.

It is illustrated in the drawing that the planar contact hole CNHA and the tower contact hole CNHB are positioned inside a planar area and spaced apart from an outer edge of each of the first light emitting area EA1, the second light emitting area EA2, and the third light emitting area EA3, but the present disclosure is not limited thereto. In another embodiment, the planar contact hole CNHA and the tower contact hole CNHB may also be positioned in a portion overlapping the non-light emitting area NLA positioned outside the light emitting area EA. The structures of the planar contact hole CNHA and the tower contact hole CNHB will be described later.

In an embodiment, the non-light emitting area NLA may be positioned to surround each of the first to third light emitting areas EA1, EA2, and EA3. The non-light emitting area NLA may assist in preventing the light emitted from each of the first to third light emitting areas EA1, EA2, and EA3 from being mixed.

FIG. 5 is a cross-sectional view illustrating an example of the display layer DPL taken along line X1-X1′ of FIG. 4. FIG. 5 illustrates a cross-sectional view of a display layer DPL included in the first sub-pixel SP1 and the third sub-pixel SP3 positioned in the portion overlapping the planar area EAp and the second sub-pixel SP2 positioned in the portion overlapping the tower area EAt in FIG. 4. Since the substrate SUB has already been mentioned, the description thereof will be omitted.

Referring to FIG. 5, a transistor layer TFTL may be positioned on the substrate SUB. The transistor layer TFTL may include a first buffer layer BF1, a lower metal layer BML, a second buffer layer BF2, a transistor TFT, a gate insulating layer GI, a first insulating layer ILD1, a capacitor electrode CPE, a second insulating layer ILD2, a first connection electrode CNE1, a first via layer VIA1, a second connection electrode CNE2, and a second via layer VIA2.

The first buffer layer BF1 may be positioned on the substrate SUB. The first buffer layer BF1 may include an inorganic film capable of preventing permeation of air or moisture. For example, the first buffer layer BF1 may include a plurality of inorganic films alternately stacked.

The lower metal layer BML may be positioned on the first buffer layer BF1. The lower metal layer BML may include an electrically conductive material such as a conductive metal and may be formed of, for example, a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the lower metal layer BML. The second buffer layer BF2 may include an inorganic film capable of preventing permeation of air or moisture. For example, the second buffer layer BF2 may include a plurality of inorganic films alternately stacked.

The transistor TFT may be disposed on the second buffer layer BF2, and may constitute a pixel circuit connected to each of the plurality of pixels PX. As an example, the transistor TFT may be a driving transistor or a switching transistor of the pixel circuit.

The transistor TFT may include an active layer ACT, a source electrode SE, a drain electrode DE, and a gate electrode GE. The active layer ACT may be positioned on the second buffer layer BF2. The active layer ACT may overlap the gate electrode GE in the third direction DR3 and may be insulated from the gate electrode GE by the gate insulating layer GI. In a portion of the active layer ACT, a material of the active layer ACT may become a conductor to form the source electrode SE and the drain electrode DE.

The gate insulating layer GI may be disposed on the active layer ACT. The gate insulating layer GI may cover the active layer ACT and the second buffer layer BF2, and may insulate the active layer ACT and the gate electrode GE from each other. The gate insulating layer GI may include a contact hole defined therein and through which the first connection electrode CNE1 penetrates.

The gate electrode GE may be positioned on the gate insulating layer GI. The gate electrode GE may overlap the active layer ACT with the gate insulating layer GI interposed therebetween. The gate electrode GE may include a conductive metal and may be formed of, for example, a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The first insulating layer ILD1 may cover the gate electrode GE and the gate insulating layer GI. The first insulating layer ILD1 may include a contact hole defined therein and through which the first connection electrode CNE1 penetrates. The contact hole of the first insulating layer ILD1 may be connected to the contact hole of the gate insulating layer GI and a contact hole of the second insulating layer ILD2 to provide a continuous contact hole.

The capacitor electrode CPE may be positioned on the first insulating layer ILD1. The capacitor electrode CPE may overlap the gate electrode GE in the third direction DR3. The capacitor electrode CPE and the gate electrode GE may form a capacitance, that is, two electrodes of a capacitor of the pixel circuit.

The second insulating layer ILD2 may cover the capacitor electrode CPE and the first insulating layer ILD1. The second insulating layer ILD2 may include a contact hole defined therein and through which the first connection electrode CNE1 penetrates. The contact hole of the second insulating layer ILD2 may be connected to the contact hole of the first insulating layer ILD1 and the contact hole of the gate insulating layer GI.

The first connection electrode CNE1 may be positioned on the second insulating layer ILD2. The first connection electrode CNE1 may electrically connect the drain electrode DE of the transistor TFT and the second connection electrode CNE2 to each other. The first connection electrode CNE1 may be inserted (or extend) into the contact holes formed in the first insulating layer ILD1, the second insulating layer ILD2, and the gate insulating layer GI and be in contact with the drain electrode DE of the transistor TFT.

The first via layer VIA1 may cover the first connection electrode CNE1 and the second insulating layer ILD2. The first via layer VIA1 may planarize a lower structure as including the various layers and elements underlying the first via layer VIA1. The first via layer VIA1 may include a contact hole defined therein and through which the second connection electrode CNE2 penetrates.

The first via layer VIA1 may include an organic insulating material. As an example, the first via layer VIA1 may include an acrylic resin, polyimide, polyamide, benzocyclobutene, or a phenol resin.

The second connection electrode CNE2 may be positioned on the first via layer VIA1. The second connection electrode CNE2 may be inserted into the contact hole formed in the first via layer VIA1 and be in contact with the first connection electrode CNE1. The second connection electrode CNE2 may electrically connect the first connection electrode CNE1 and an anode electrode AE to each other. As being in contact, elements may form an interface therebetween.

The second via layer VIA2 may be positioned in a portion overlapping the light emitting area EA and the non-light emitting area NLA. The second via layer VIA2 may entirely cover the second connection electrode CNE2 and the first via layer VIA1.

The second via layer VIA2 may include an organic material. As an example, the second via layer VIA2 may include an acrylic resin, polyimide, polyamide, benzocyclobutene, or a phenol resin.

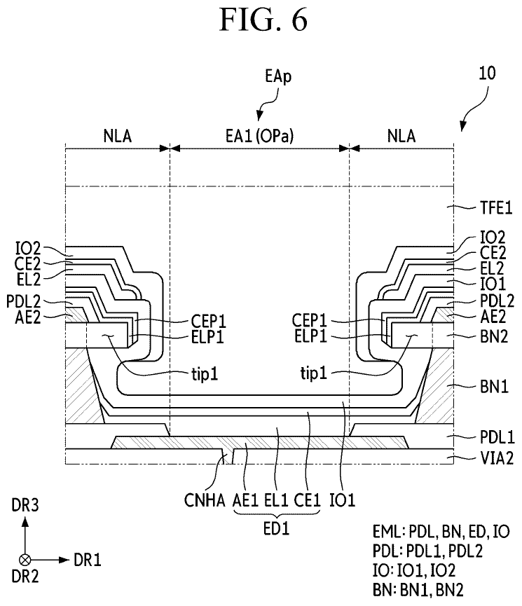

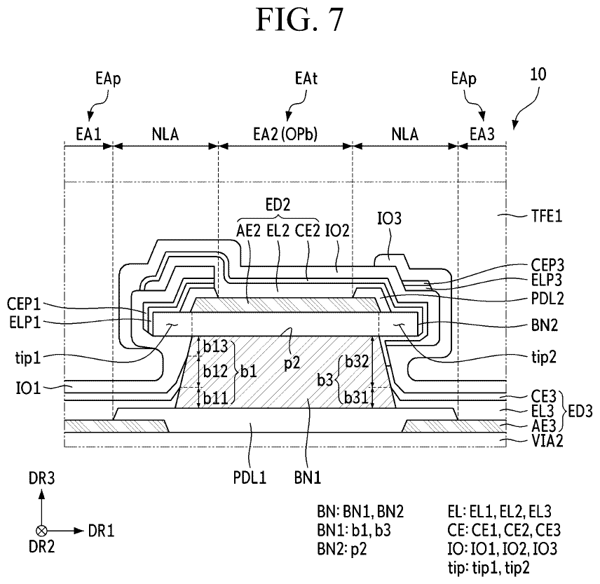

FIG. 6 is an enlarged cross-sectional view of a display element layer EML overlapping a first light emitting area EA1 included in a planar area EAp in FIG. 5, and FIG. 7 is an enlarged cross-sectional view of a display element layer EML overlapping a second light emitting area EA2 included in a tower area EAt in FIG. 5.

Referring to FIGS. 5 to 7, a display element layer EML may be disposed on the transistor layer TFTL. The display element layer EML may include a pixel defining layer PDL, a bank structure BN, a light emitting element ED, and an element inorganic layer IO.

In cross-section view, the light emitting area EA included in the display device 10 may include a recessed layered structure constituting a planar area EAp and a protruded layered structure constituting a tower area EAt which are cross-repeatedly positioned. The planar area EAp and the tower area Eat may be spaced apart from each other in a direction along the transistor layer TFTL, with the non-light emitting area NLA interposed therebetween.

As described above, the planar area EAp may include the first light emitting area EA1 and the third light emitting area EA3, and the tower area EAt may include the second light emitting area EA2. As described above, the first light emitting area EA1, the second light emitting area EA2, and third light emitting area EA3 may emit light of different colors within a same pixel PX or a same pixel group PXG, without being limited thereto.

The pixel defining layer PDL may include a first pixel defining layer PDL1 and a second pixel defining layer PDL2.

The first pixel defining layer PDL1 may be positioned in contact with the second via layer VIA2 in a portion overlapping the non-light emitting area NLA. The first pixel defining layer PDL1 may be positioned in a portion overlapping the second light emitting area EA2 included in the tower area EAt, while being excluded from the planar area EAp.

The first pixel defining layer PDL1 may define the first opening OPa. The first pixel defining layer PDL1 may be positioned to surround the first opening OPa. The planar area EAp according to an embodiment may be defined by the first opening OPa.

The first pixel defining layer PDL1 may insulate and separate a first anode electrode AE1 and a third anode electrode AE3 in a planar direction along the transistor layer TFTL, such as along the first direction DR1. In addition, the first pixel defining layer PDL1 may insulate and separate the bank structure BN, and the first anode electrode AE1 and the third anode electrode AE3, in the third direction DR3.

The first pixel defining layer PDL1 may include an inorganic insulating material. As an example, the first pixel defining layer PDL1 may include at least one of silicon nitride, silicon oxide, and silicon oxynitride.

The bank structure BN as a solid material portion of a bank layer may be positioned on the first pixel defining layer PDL1, in a portion overlapping the non-light emitting area NLA. The bank structure BN may be positioned in a portion overlapping the second light emitting area EA2 included in the tower area EAt, while being excluded from the planar area EAp. The bank structure BN may separate the first light emitting element ED1 and the third light emitting element ED3. The bank structure BN may define a bank opening of the bank layer which corresponds to a respective light emission area (e.g., light emitting area) at the planar area EAp.

The bank structure BN may include a metal bank layer BN1 and an insulating bank layer BN2. Bank structures BN which are spaced apart from each other by a lower bank sub-opening may be coplanar with each other. Insulating bank layers BN2 which are spaced apart from each other by an upper bank sub-opening may be coplanar with each other.

The metal bank layer BN1 may be positioned in contact with the first pixel defining layer PDL1. The metal bank layer BN1 may include a metal material with high electrical conductivity. As an example, the metal bank layer BN1 may include at least one of aluminum (Al) and copper (Cu).

The metal bank layer BN1 may include (or define) a first side surface b1 as a bank first side surface positioned in a direction toward (or facing) the first light emitting element ED1, and a second side surface b3 as a bank second side surface which is opposite to the first side surface b1. The first side surface b1 and the second side surface b3 of the metal bank layer BN1 may be positioned to be recessed relative to a side surface of the first pixel defining layer PDL1, in the first direction DR1. In other words, a portion of the first pixel defining layer PDL1 in the portion overlapping the non-light emitting area NLA may be exposed to outside the bank structure BN, without being covered by the metal bank layer BN1.

The insulating bank layer BN2 may be positioned in contact with the metal bank layer BN1 in the portion overlapping the non-light emitting area NLA. The insulating bank layer BN2 may be positioned in the portion overlapping the second light emitting area EA2 included in the tower area EAt, while being excluded from the planar area EAp.

The insulating bank layer BN2 may have a first tip tip1 which protrudes further toward the planar area EAp than the first side surface b1 of the metal bank layer BN1, and a second tip tip2 which protrudes further toward the planar area EAp than the second side surface b3 thereof. The first tip tip1 of the insulating bank layer BN2 may protrude in a direction opposite to the first direction DR1 toward the first light emitting element ED1, and the second tip tip2 thereof may protrude in the first direction DR1 toward the third light emitting element ED3.

An undercut may be formed by the tip of the insulating bank layer BN2 and a sidewall of the metal bank layer BN1. In other words, the bank structure BN may have an overhang structure.

In the display device 10 according to an embodiment, as the insulating bank layer BN2 includes the tip, the light emitting layer EL and the cathode electrode CE may be formed without using a separate fine metal mask. The fabricating process thereof will be described later.

The insulating bank layer BN2 may include an inorganic insulating material. As an example, the insulating bank layer BN2 may include at least one of silicon nitride, silicon oxide, and silicon oxynitride. Accordingly, the insulating bank layer BN2 may separate and insulate (e.g., electrically) the metal bank layer BN1 and the second anode electrode AE2.

The second pixel defining layer PDL2 according to an embodiment may be positioned in contact with the insulating bank layer BN2 in the portion overlapping the non-light emitting area NLA.

The second pixel defining layer PDL2 may define the second opening OPb. The second pixel defining layer PDL2 may be positioned to surround the second opening OPb. The tower area EAt included in the light emitting area EA may be defined by the second opening OPb.

The second pixel defining layer PDL2 may include an inorganic insulating material. As an example, the second pixel defining layer PDL2 may include at least one of silicon nitride, silicon oxide, and silicon oxynitride.

The light emitting element ED according to an embodiment may be positioned in a portion overlapping the light emitting area EA. The light emitting element ED may include a first light emitting element ED1 disposed in the first light emitting area EA1 included in the planar area EAp, a second light emitting element ED2 disposed in the second light emitting area EA2 included in the tower area EAt, and a third light emitting element ED3 disposed in the third light emitting area EA3 included in the planar area EAp.

The first light emitting element ED1 may include a first anode electrode AE1, a first light emitting layer EL1, and a first cathode electrode CE1, the second light emitting element ED2 may include a second anode electrode AE2, a second light emitting layer EL2, and a second cathode electrode CE2, and the third light emitting element ED3 may include a third anode electrode AE3, a third light emitting layer EL3, and a third cathode electrode CE3.

The first light emitting element ED1, the second light emitting element ED2, and the third light emitting element ED3 may emit light of different colors. As an example, the first light emitting element ED1 may emit blue light, the second light emitting element ED2 may emit green light, and the third light emitting element ED3 may emit red light. However, the present disclosure is not limited thereto, and in another embodiment, the first light emitting element ED1 may emit red light, the second light emitting element ED2 may emit green light, and the third light emitting element ED3 may emit blue light.

In an embodiment, the first light emitting element ED1 and the third light emitting element ED3 may be positioned on the same plane (e.g., coplanar with each other) in the first direction DR1. The meaning of being positioned on the same plane as described above may mean being positioned on the same line in the first direction DR1. In addition, the second light emitting element ED2 may be positioned between the first light emitting element ED1 and the third light emitting element ED3, along the first direction DR1. The second light emitting element ED2 may be positioned to be in a plane which is higher in a direction toward one side of the third direction DR3 than the first light emitting element ED1 and the third light emitting element ED3.

In other words, the second light emitting element ED2 may be positioned in a stacked structure portion which protrudes further in a direction toward one side of the third direction DR3 than the first light emitting element ED1 and the third light emitting element ED3, and the first light emitting element ED1 and the third light emitting element ED3 may be positioned in a stacked structure portion which is further recessed or grooved in a direction toward the other side of the third direction DR3 than the second light emitting element ED2.

In the display device 10 according to an embodiment, the light emitting area EA may be efficiently disposed by disposing the first light emitting element ED1 positioned in the portion overlapping the planar area EAp, the second light emitting element ED2 positioned in the portion overlapping the tower area EAt, and the third light emitting element ED3 positioned in the portion overlapping the planar area EAp to be cross-repeated. Accordingly, the display device 10 according to an embodiment may provide an ultra-high resolution electronic device 1 having high pixel integration.

The anode electrode AE according to an embodiment may be positioned in a portion overlapping the light emitting area EA.

The anode electrode AE may have a stacked film structure in which a material layer having a high work function, made of (or including) indium tin oxide (ITO), indium zinc oxide (IZO), zinc oxide (ZnO), or indium oxide (In₂O₃) and a reflective material layer made of silver (Ag), magnesium (Mg), aluminum (Al), platinum (Pt), lead (Pd), palladium (Pd), gold (Au), nickel (Ni), neodymium (Nd), iridium (Ir), chromium (Cr), lithium (Li), or a combination thereof are stacked. As an example, the anode electrode AE may have a multilayer structure of ITO/Mg, ITO/MgF₂, ITO/Ag, and ITO/Ag/ITO, but is not limited thereto.

The anode electrode AE may include a plurality of anode electrodes including a first anode electrode AE1 disposed in the first light emitting area EA1 included in the planar area EAp, a second anode electrode AE2 disposed in the second light emitting area EA2 included in the tower area EAt, and a third anode electrode AE3 disposed in the third light emitting area EA3 included in the planar area EAp. The first anode electrode AE1, the second anode electrode AE2, and the third anode electrode AE3 may be spaced apart from each other.

In an embodiment, the first anode electrode AE1 and the third anode electrode AE3 may be positioned in contact with the second via layer VIA2 in a portion overlapping the planar area EAp. The second via layer VIA2 may represent a base layer on which various layers, patterns, etc. of the display element layer EML is provided.

The first anode electrode AE1 and the third anode electrode AE3 may be positioned on the same plane in the first direction DR1. The first anode electrode AE1 and the third anode electrode AE3 may fill a planar contact hole CNHA penetrating through the second via layer VIA2. The first anode electrode AE1 and the third anode electrode AE3 may be electrically connected to the second connection electrode CNE2 through the planar contact hole CNHA.

In the portion overlapping the non-light emitting area NLA, the first anode electrode AE1 and the third anode electrode AE3 may be covered by the first pixel defining layer PDL1. The first pixel defining layer PDL1 may be positioned to surround edges of the first anode electrode AE1 and the third anode electrode AE3.

In an embodiment, the second anode electrode AE2 may be positioned on the insulating bank layer BN2 in the portion overlapping the tower area EAt.

In an embodiment, the second anode electrode AE2 may be positioned between the first anode electrode AE1 and the third anode electrode AE3, and may be positioned to be higher in a direction toward one side of the third direction DR3 than the first anode electrode AE1 and the third anode electrode AE3.

In other words, the second anode electrode AE2 may be positioned in a portion which protrudes further in a direction toward one side of the third direction DR3 than the first anode electrode AE1 and the third anode electrode AE3, and the first anode electrode AE1 and the third anode electrode AE3 may be positioned in a portion which is further recessed or grooved in a direction toward the other side of the third direction DR3 than the second anode electrode AE2.

In the portion overlapping the non-light emitting area NLA, the second anode electrode AE2 may be covered by the second pixel defining layer PDL2. The second pixel defining layer PDL2 may be positioned to surround the edge of the second anode electrode AE2.

The light emitting layer EL according to an embodiment may be positioned on the anode electrode AE. The light emitting layer EL may be positioned in a portion overlapping the light emitting area EA and the non-light emitting area NLA.

The light emitting layer EL may be an organic light emitting layer made of an organic material. The light emitting layer EL according to an embodiment may be formed through a deposition process and a photo pattern process without using a separate fine metal mask in the fabricating process. The fabricating process thereof will be described later.

The light emitting layer EL may include a first light emitting layer EL1 disposed in the first light emitting area EA1 included in the planar area EAp, a second light emitting layer EL2 disposed in the second light emitting area EA2 included in the tower area EAt, and a third light emitting layer EL3 disposed in the third light emitting area EA3 included in the planar area EAp. The first light emitting layer EL1, the second light emitting layer EL2, and the third light emitting layer EL3 may be spaced apart from each other.

The first light emitting layer EL1, the second light emitting layer EL2, and the third light emitting layer EL3 may emit light of different colors. As an example, the first light emitting layer EL1 may emit blue light, the second light emitting layer EL2 may emit green light, and the third light emitting layer EL3 may emit red light. However, the present disclosure is not limited thereto, and the first light emitting layer EL1 may emit red light, the second light emitting layer EL2 may emit green light, and the third light emitting layer EL3 may emit blue light.

In an embodiment, the first light emitting layer EL1 and the third light emitting layer EL3 may be positioned on the same plane in the first direction DR1. In other words, it may mean that the first light emitting layer EL1 and the third light emitting layer EL3 may be positioned on the same line in the first direction DR1.

The first light emitting layer EL1 may cover the first anode electrode AE1 and the first pixel defining layer PDL1 and may be in contact with the first side surface b1 of the metal bank layer BN1. The third light emitting layer EL3 may cover the third anode electrode AE3 and the first pixel defining layer PDL1 and may be in contact with the second side surface b3 of the metal bank layer BN1.

In an embodiment, the second light emitting layer EL2 may be positioned on the insulating bank layer BN2 in the portion overlapping the tower area EAt. The second light emitting layer EL2 may be in contact with and cover the second anode electrode AE2 and entirely cover the second pixel defining layer PDL2.

In an embodiment, the second light emitting layer EL2 may be positioned between the first light emitting layer EL1 and the third light emitting layer EL3, and may be positioned to be higher in a direction toward one side of the third direction DR3 than the first light emitting layer EL1 and the third light emitting layer EL3. In other words, the second light emitting layer EL2 may be positioned in a portion which protrudes further in a direction toward one side of the third direction DR3 than the first light emitting layer EL1 and the third light emitting layer EL3, and the first light emitting layer EL1 and the third light emitting layer EL3 may be positioned in a portion which is further recessed or grooved in a direction toward the other side of the third direction DR3 than the second light emitting layer EL2.

In cross-sectional view, a first width We1 of the first opening OPa in the first direction DR1 may be greater than a second width We2 of the second opening OPb. In other words, in cross-sectional view, the first width We1 of the first opening OPa defining the planar area EAp may be greater than the second width We2 of the second opening OPb defining the tower area EAt. This may mean that widths of the first light emitting element ED1 and the third light emitting element ED3 positioned in the portion overlapping the first opening OPa are formed to be greater than a width of the second light emitting element ED2 positioned in the portion overlapping the second opening OPb.

For example, when the second light emitting element ED2 having a relatively narrow width compared to the first light emitting element ED1 and the third light emitting element ED3 is positioned in the same planar area EAp as the first light emitting element ED1 and the third light emitting element ED3, a deposition efficiency of the second light emitting layer EL2 included in the second light emitting element ED2 may be reduced.

Specifically, when the second light emitting element ED2 having a relatively narrow width compared to the first light emitting element ED1 and the third light emitting element ED3 is positioned in the planar area EAp, a proportion of an area covered by the tip of the insulating bank layer BN2 may be relatively large, and accordingly, the deposition efficiency of the second light emitting layer EL2 may be reduced in a portion overlapping the tip of the insulating bank layer BN2.

For example, when the deposition efficiency of the material forming the second light emitting layer EL2 is reduced in the portion overlapping the tip of the insulating bank layer BN2, this may cause defects in the light emitting reliability of the display device 10 (e.g., defects in the light emitting layer shadow). The defects in the light emitting reliability may occur because a deposition thickness of the second light emitting layer EL2 in the portion overlapping the tip of the insulating bank layer BN2 is deposited to be 10% or more lower than a deposition thickness of the second light emitting layer EL2 in a portion which does not overlap the tip of the insulating bank layer BN2.

Accordingly, in the display device 10 according to an embodiment, as the second light emitting element ED2 having a relatively narrow width compared to the first light emitting element ED1 and the third light emitting element ED3 is disposed in a different plane by the stacked structure overlapping the tower area EAt, the second light emitting layer EL2 may be disposed to be positioned above the tip of the insulating bank layer BN2. Accordingly, the display device 10 according to an embodiment may provide an ultra-high resolution display device 10 having high pixel PX integration without the defects in the light emitting reliability.

The cathode electrode CE according to an embodiment may be positioned on the light emitting layer EL. The cathode electrode CE may be positioned in a portion overlapping the light emitting area EA and the non-light emitting area NLA.

The cathode electrode CE may transmit light generated from the light emitting layer EL by including a transparent conductive material. The cathode electrode CE may be formed through a deposition process and a photo pattern process without using a separate fine metal mask in the fabricating process. The fabricating process thereof will be described later.

The cathode electrode CE may include a metal layer having a low work function, and may further include a transparent metal oxide layer depending on the embodiment. As an example, the cathode electrode CE may include a material layer having a low work function, such as Li, Ca, LiF/Ca, LiF/Al, Al, Mg, Ag, Pt, Pd, Ni, Au, Nd, Ir, Cr, BaF, Ba, or a compound or combination thereof (e.g., a combination of Ag and Mg, etc.).

The cathode electrode CE may include a first cathode electrode CE1 disposed in the first light emitting area EA1 included in the planar area EAp, a second cathode electrode CE2 disposed in the second light emitting area EA2 included in the tower area EAt, and a third cathode electrode CE3 disposed in the third light emitting area EA3 included in the planar area EAp. In an embodiment, the first cathode electrode CE1 may be spaced apart from the second cathode electrode CE2 and the third cathode electrode CE3.

In an embodiment, the first cathode electrode CE1 and the third cathode electrode CE3 may be positioned on the same plane in the first direction DR1. The first cathode electrode CE1 may cover the first pixel defining layer PDL1 and may be in contact with the first side surface b1 of the metal bank layer BN1. In addition, the third cathode electrode CE3 may cover the first pixel defining layer PDL1 and may be in contact with the second side surface b3 of the metal bank layer BN1. Accordingly, the first cathode electrode CE1 may be electrically connected to the third cathode electrode CE3 through the metal bank layer BN1.

In an embodiment, the second cathode electrode CE2 may be positioned on the insulating bank layer BN2 in the portion overlapping the tower area EAt. The second cathode electrode CE2 may be in contact with and cover the second light emitting layer EL2 and entirely cover the second pixel defining layer PDL2.

In an embodiment, the second cathode electrode CE2 may be in contact with a lower surface p2 of the insulating bank layer BN2 which is exposed at the tip, extend therefrom, and be in contact with the second side surface b3 of the metal bank layer BN1. Accordingly, the second cathode electrode CE2 may be electrically connected to the first cathode electrode CE1 and the third cathode electrode CE3 through the metal bank layer BN1.

However, the second cathode electrode CE2 is not in contact with the first side surface b1 of the metal bank layer BN1, but may be electrically connected to the first cathode electrode CE1 through the metal bank layer BN1.

In some embodiments, the second cathode electrode CE2 may also be directly connected to the third cathode electrode CE3 on the second side surface b3 of the metal bank layer BN1. However, the present disclosure is not limited thereto.

A first organic pattern ELP1 according to an embodiment may be positioned on the insulating bank layer BN2. The first organic pattern ELP1 may be positioned on the first tip tip1 of the insulating bank layer BN2 in a portion overlapping the non-light emitting area NLA.

It is illustrated in the drawing that the first organic pattern ELP1 is not in contact with the lower surface p2 of the insulating bank layer BN2, but the present disclosure is not limited thereto. Depending on the embodiments, the first organic pattern ELP1 may also be in contact with a portion of the lower surface p2 of the insulating bank layer BN2. However, the first organic pattern ELP1 does not cover the entirety of the lower surface p2 of the insulating bank layer BN2, but may expose a portion of the lower surface p2 of the insulating bank layer BN2. Accordingly, the first organic pattern ELP1 may be spaced apart from the first side surface b1 of the metal bank layer BN1.

The first organic pattern ELP1 may include the same material as the first light emitting layer EL1 and may be spaced apart from the first light emitting layer EL1. The first organic pattern ELP1 may be formed by performing the process of forming the first light emitting layer EL1 in the process of fabricating the display device 10 through a full-surface deposition process without using a separate fine metal mask. Here, a first light emitting material may be provided on a full-surface of the underlying stacked structure, and disconnected via the tips to provide the first organic pattern ELP1 and the first light emitting layer EL1 as respective portions of a same material layer (e.g., a first light emitting material layer). For example, as being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

A first electrode pattern CEP1 according to an embodiment may be positioned on the insulating bank layer BN2. The first electrode pattern CEP1 may be positioned on the first tip tip1 of the insulating bank layer BN2 in a portion overlapping the non-light emitting area NLA.

It is illustrated in the drawing that the first electrode pattern CEP1 is not in contact with the lower surface p2 of the insulating bank layer BN2, but the present disclosure is not limited thereto. Depending on the embodiments, the first electrode pattern CEP1 may also be in contact with a portion of the lower surface p2 of the insulating bank layer BN2. However, the first electrode pattern CEP1 does not cover the entirety of the lower surface p2 of the insulating bank layer BN2, but may expose a portion of the lower surface p2 of the insulating bank layer BN2. Accordingly, the first electrode pattern CEP1 may be spaced apart from the first side surface b1 of the metal bank layer BN1.

The first electrode pattern CEP1 may include the same material as the first cathode electrode CE1 and may be spaced apart from the first cathode electrode CE1. The first electrode pattern CEP1 may be formed by performing the process of forming the first cathode electrode CE1 in the process of fabricating the display device 10 through a full-surface deposition process without using a separate fine metal mask. Here, a first cathode electrode material may be provided on a full-surface of the underlying stacked structure, and disconnected via the tips to provide the first electrode pattern CEP1 and the first cathode electrode CE1 as respective portions of a same material layer (e.g., a first cathode electrode material layer).

The element inorganic layer IO according to an embodiment may be positioned on the light emitting element ED. The element inorganic layer IO may completely cover the light emitting element ED and prevent oxygen or moisture from permeating into the light emitting element ED.

The element inorganic layer IO may include an inorganic insulating material. As an example, the element inorganic layer IO may include at least one of silicon nitride, silicon oxide, and silicon oxynitride.

The element inorganic layer IO may include a first element inorganic layer IO1 disposed in the first light emitting area EA1 included in the planar area EAp, a second element inorganic layer IO2 disposed in the second light emitting area EA2 included in the tower area EAt, and a third element inorganic layer IO3 disposed in the third light emitting area EA3 included in the planar area EAp.

The first element inorganic layer IO1 as a first element inorganic pattern may entirely cover the first light emitting element ED1 in a portion overlapping the first light emitting area EA1, and may cover the insulating bank layer BN2 and the second pixel defining layer PDL2 in a portion overlapping the non-light emitting area NLA.

The second element inorganic layer IO2 as a second element inorganic pattern may entirely cover the second light emitting element ED2 in a portion overlapping the second light emitting area EA2, and may cover the second light emitting element ED2 and the first element inorganic layer IO1 or the third element inorganic layer IO3 in a portion overlapping the non-light emitting area NLA. The second element inorganic layer IO2 may be in contact with at least one of the first element inorganic layer IO1 or the third element inorganic layer IO3 in the portion overlapping the non-light emitting area NLA.

The third element inorganic layer IO3 as a third element inorganic pattern may entirely cover the third light emitting element ED3 in a portion overlapping the third light emitting area EA3, and may cover the insulating bank layer BN2 and the second pixel defining layer PDL2 in a portion overlapping the non-light emitting area NLA.

In some embodiments, the first side surface b1 of the metal bank layer BN1 may include a first portion b11 as a first thickness portion, a second portion b12 as a second thickness portion, and a third portion b13 as a third thickness portion depending on the contact structure. The first portion b11 may be a portion which is in contact with the first light emitting layer EL1, the second portion b12 may be a portion which is in contact with the first cathode electrode CE1, and the third portion b13 may be a portion which is in contact with the first element inorganic layer IO1. The first side surface b1 may be formed of the first portion b11, the second portion b12, and the third portion b13 together with each other.

In addition, the second side surface b3 of the metal bank layer BN1 may include a first portion b31 as a lower thickness portion and a second portion b32 as an upper thickness portion depending on the contact structure. The first portion b31 may be a portion which is in contact with the third light emitting layer EL3, and the second portion b32 may be a portion which is in contact with the second cathode electrode CE2 and the third cathode electrode CE3. The second side surface b3 may be formed of the first portion b31 and the second portion b32 together with each other. In other words, the element inorganic layer IO may not be in contact with the second side surface b3.

A third organic pattern ELP3 according to an embodiment may be positioned on the insulating bank layer BN2. The third organic pattern ELP3 may be positioned on the second tip tip2 of the insulating bank layer BN2 in a portion overlapping the non-light emitting area NLA.

As illustrated in FIGS. 5 and 7, the third organic pattern ELP3 may be in contact with and positioned on the second element inorganic layer IO2 in a portion overlapping the other side in the first direction DR1 based on the third light emitting element ED3. In addition, the third organic pattern ELP3 may be in contact with and positioned on the insulating bank layer BN2 and the second pixel defining layer PDL2 in a portion overlapping one side in the first direction DR1 based on the third light emitting element ED3. This may be due to the fabricating process order of the first to third light emitting elements ED1, ED2, and ED3. The fabricating process thereof will be described later.

The third organic pattern ELP3 may include the same material as the third light emitting layer EL3 and may be spaced apart from the third light emitting layer EL3. The third organic pattern ELP3 may be formed by performing the process of forming the third light emitting layer EL3 in the process of fabricating the display device 10 through a full-surface deposition process without using a separate fine metal mask. Here, a third light emitting material may be provided on a full-surface of the underlying stacked structure, and disconnected via the tips to provide the third organic pattern ELP3 and the third light emitting layer EL3 as respective portions of a same material layer (e.g., a third light emitting material layer).

A third electrode pattern CEP3 according to an embodiment may be positioned on the third organic pattern ELP3. The third electrode pattern CEP3 may be positioned on the second tip tip2 of the insulating bank layer BN2 in a portion overlapping the non-light emitting area NLA.

The third electrode pattern CEP3 may include the same material as the third cathode electrode CE3 and may be spaced apart from the third cathode electrode CE3. The third electrode pattern CEP3 may be formed by performing the process of forming the third cathode electrode CE3 in the process of fabricating the display device 10 through a full-surface deposition process without using a separate fine metal mask. Here, a third cathode electrode material may be provided on a full-surface of the underlying stacked structure, and disconnected via the tips to provide the third electrode pattern and the third cathode electrode CE3 as respective portions of a same material layer (e.g., a third cathode electrode material layer).

The thin film encapsulation layer TFEL according to an embodiment may be positioned on the display element layer EML. The thin film encapsulation layer TFEL may include an organic encapsulation layer TFE1 and an inorganic encapsulation layer TFE3.

The organic encapsulation layer TFE1 according to an embodiment may be positioned on the element inorganic layer IO. As an example, the organic encapsulation layer TFE1 may be entirely in contact with and cover the first element inorganic layer IO1, the second element inorganic layer IO2, and the third element inorganic layer IO3.

The organic encapsulation layer TFE1 may planarize the steps formed according to a profile of elements within the lower structure (e.g., an underlying stacked structure).

The organic encapsulation layer TFE1 may include a polymer-based material. As an example, the organic encapsulation layer TFE1 may include an acrylic resin, a silicone resin, an epoxy resin, a silicone acrylic resin, polyimide, or polyethylene.

The inorganic encapsulation layer TFE3 according to an embodiment may be positioned on the organic encapsulation layer TFE1. The inorganic encapsulation layer TFE3 may protect the lower structure from permeation of moisture and oxygen. In some embodiments, the inorganic encapsulation layer TFE3 may also be omitted.

The inorganic encapsulation layer TFE3 may include an inorganic insulating material. As an example, the inorganic encapsulation layer TFE3 may include at least one of silicon nitride, silicon oxide, and silicon oxynitride.

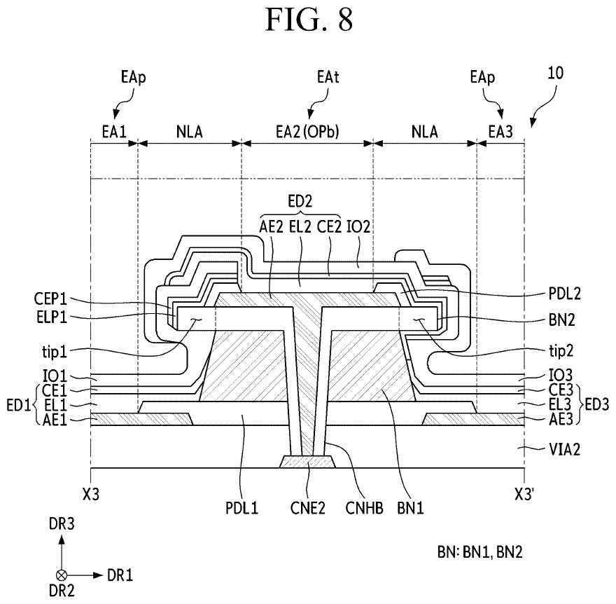

FIG. 8 is a cross-sectional view illustrating an example of the display element layer EML taken along line X3-X3′ of FIG. 4. FIG. 8 illustrates a cross-sectional structure of the tower contact hole CNHB positioned in a portion overlapping the tower area EAt. The tower contact hole CNHB may be positioned at a different position along the length of the tower area EAt than the planar contact hole CNHA (e.g., like along the line X1-X1′ which is in a different length position than the line X3-X3′ in FIG. 4).

Referring to FIG. 8, the tower contact hole CNHB according to an embodiment may be positioned in a portion overlapping the tower area EAt. However, the tower contact hole CNHB is not limited thereto and may also be positioned in a portion overlapping the non-light emitting area NLA adjacent to the tower area EAt.

The tower contact hole CNHB may penetrate through the second via layer VIA2, the first pixel defining layer PDL1, and the bank structure BN. In other words, in the portion overlapping the tower area EAt, the second via layer VIA2, the first pixel defining layer PDL1, and the bank structure BN may be positioned to surround the tower contact hole CNHB.

The second anode electrode AE2 may fill the tower contact hole CNHB. The second anode electrode AE2 may be electrically connected to the second connection electrode CNE2 through the tower contact hole CNHB.

The insulating bank layer BN2 may be positioned on the metal bank layer BN1. The insulating bank layer BN2 may be positioned between the metal bank layer BN1 and the second anode electrode AE2 in the portion overlapping the tower contact hole CNHB. Accordingly, the insulating bank layer BN2 may insulate the metal bank layer BN1 and the second anode electrode AE2.

In the portion overlapping the tower contact hole CNHB, the first light emitting element ED1 and the third light emitting element ED3 may be spaced apart from each other in the first direction DR1 with the tower contact hole CNHB interposed therebetween. In addition, in the portion overlapping the tower contact hole CNHB, the first element inorganic layer IO1 and the third element inorganic layer IO3 may be spaced apart from each other in the first direction DR1 with the tower contact hole CNHB interposed therebetween. In addition, in the portion overlapping the tower contact hole CNHB, the second light emitting element ED2 and the second element inorganic layer IO2 may overlap the tower contact hole CNHB in the third direction DR3. Other redundant descriptions will be omitted.

Hereinafter, a method for fabricating (or providing) the display element layer EML included in the display device 10 of FIG. 5 will be described.

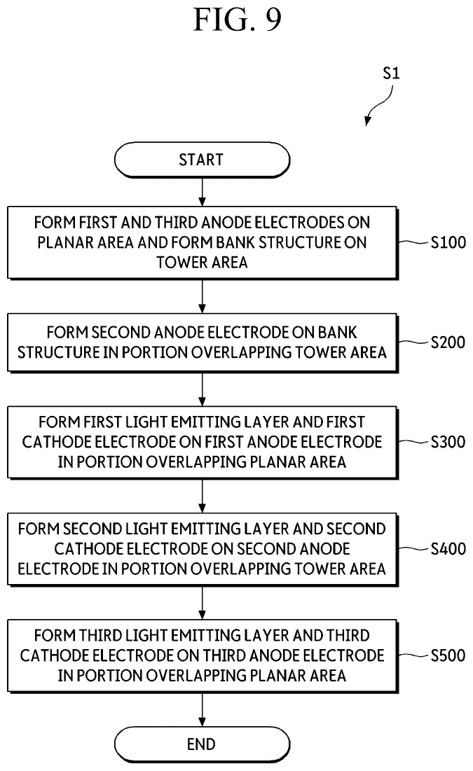

FIG. 9 is a flowchart illustrating a method for fabricating (or providing) the display element layer EML shown in the cross-section of FIG. 5.

Referring to FIG. 9, a method S1 for fabricating a display device 10 according to an embodiment may include a process (S100) of forming a first anode electrode and a third anode electrode of a first anode electrode layer, on a planar area EAp of a base layer, and forming a bank structure BN on a tower area EAt of the base layer, a process (S200) of forming a second anode electrode of a second anode electrode layer on the bank structure BN in a portion overlapping the tower area EAt, a process (S300) of forming a first light emitting layer EL1 and a first cathode electrode CE1 on the first anode electrode AE1 in a portion overlapping the planar area EAp, a process (S400) of forming a second light emitting layer EL2 and a second cathode electrode CE2 on the second anode electrode AE2 in the portion overlapping the tower area EAt, and a process (S500) of forming a third light emitting layer EL3 and a third cathode electrode CE3 on the third anode electrode AE3 in the portion overlapping the planar area EAp. In an embodiment, the first to third light emitting elements may be formed in sequence.

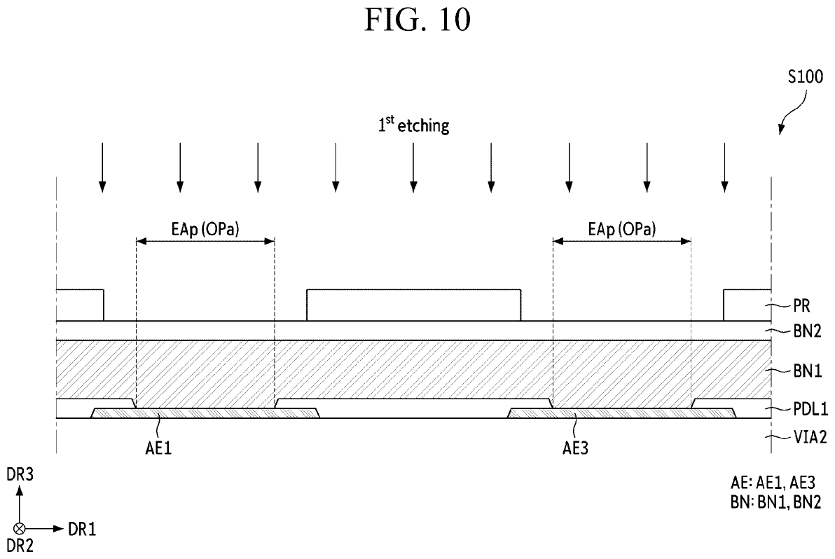

FIGS. 10 to 12 are cross-sectional views illustrating process S100 of FIG. 9.

The process (S100) of forming a first anode electrode AE1 and a third anode electrode AE3 on a planar area EAp, and forming a bank structure BN on a tower area EAt will be described with reference to FIGS. 10 to 12.

First, a plurality of anode electrodes AE of a first anode electrode layer are formed on a second via layer VIA2. In the present process, the plurality of anode electrodes AE may be positioned on the same line in a first direction DR1 that is, coplanar with each other. The anode electrode AE formed in the present process may include a first anode electrode AE1 and a third anode electrode AE3. The first anode electrode AE1 and the third anode electrode AE3 of the first anode electrode layer may be spaced apart from each other in the first direction DR1. In the present process, the anode electrode AE may be formed through a sputtering process and a photo patterning process which form at least one of the aforementioned metal materials.

Next, a first pixel defining layer PDL1 is formed to include solid portions which cover an edge of each of the first anode electrode AE1 and the third anode electrode AE3, and pixel openings defined between the solid portions. In the present process, the first pixel defining layer PDL1 may be formed through a deposition process and a photo patterning process which form at least one of the aforementioned inorganic materials.

In the present process, the first pixel defining layer PDL1 may define a first opening Opa (e.g., a pixel opening). The first pixel defining layer PDL1 may expose each of the first anode electrode AE1 and the third anode electrode AE3 to outside the first pixel defining layer PDL1, in a portion overlapping the first opening OPa. The first opening OPa may define a planar area EAp.

Next, a bank structure BN is formed on the first anode electrode AE1, the third anode electrode AE3, and the first pixel defining layer PDL1. The bank structure BN may include a metal bank layer BN1 and an insulating bank layer BN2. The metal bank layer BN1 and the insulating bank layer BN2 may be sequentially stacked.

In the present process, the metal bank layer BN1 as a preliminary metal bank material layer may entirely cover the first anode electrode AE1, the third anode electrode AE3, and the first pixel defining layer PDL1, and the insulating bank layer BN2 as a preliminary insulating bank material layer may entirely cover the preliminary metal bank material layer BN1.

In the present process, the metal bank layer BN1 and the insulating bank layer BN2 may include different materials. As an example, the metal bank layer BN1 may include an electrically conductive metal material, and the insulating bank layer BN2 may include an inorganic insulating material. The redundant descriptions will be omitted.

Next, referring to the stacked structure in FIG. 10, a plurality of photoresists PR are formed on the insulating bank layer BN2. The plurality of photoresists PR may be formed in a portion overlapping the first pixel defining layer PDL1. The plurality of photoresists PR may be spaced apart from each other.

Next, a first etching process is performed using the plurality of photoresists PR as a mask. As an example, in the first etching process, a dry etching process and a wet etching process may be sequentially performed.

First, a dry etching process is performed during the first etching process.

For example, the dry etching process may be performed through a reactive ion etching (RIE) process using reactive gases such as CHF₃, CH₃F, CH₂F₂, CHF₆, CF₄, C₂F₆, and C₃F₆, and sputtering gases such as Ar, and O₂/Ar. In this case, an inductively coupled plasma (ICP) source or a capacitively coupled plasma (CCP) source may be used as a plasma source.

In the present process, both the metal bank layer BN1 and the insulating bank layer BN2 which do not overlap the photoresist PR may be removed, and as a result, the first anode electrode AE1 and the third anode electrode AE3 may be exposed again to outside both the first pixel defining layer PDL1 and the bank structure BN, in a portion overlapping the planar area EAp or the first opening OPa.

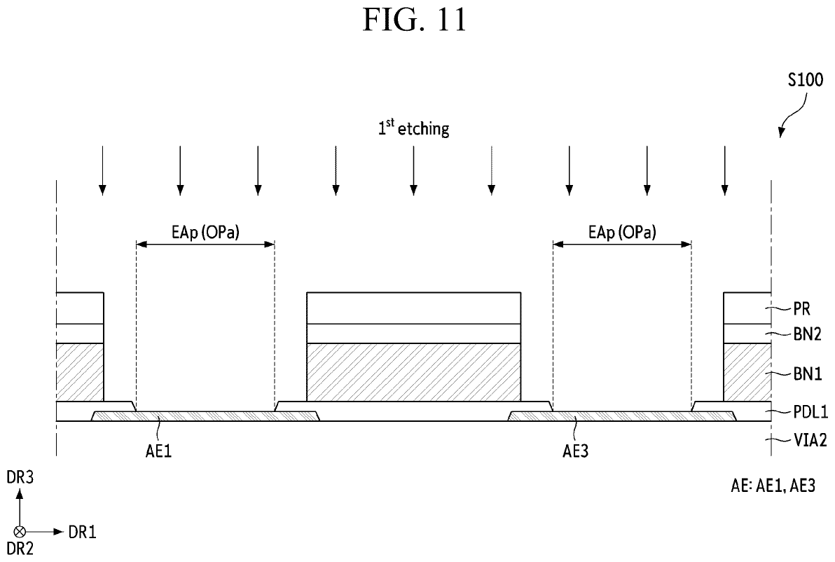

As illustrated in FIG. 11, in the present process, material layers of the metal bank layer BN1 and the insulating bank layer BN2 positioned to overlap the photoresists PR may be isotropically removed. Specifically, a side surface of the metal bank layer BN1 and a side surface of the insulating bank layer BN2 positioned to overlap the photoresists PR may be positioned on the same line. Here, the side surfaces of the metal bank layer BN1 and a side surface of the insulating bank layer BN2 may be coplanar with each other along the thickness direction (e.g., the third direction DR3).

Secondly, a wet etching process is performed during the second etching process.

For example, the wet etching process may be performed using a liquid chemical solution such as a hydrofluoric acid solution, a nitric acid solution, a tetramethylammonium hydroxide solution, and a potassium hydroxide solution.

In the present process, the metal bank layer BN1 and the insulating bank layer BN2 including different materials may have different etching selectivities. Accordingly, in this process, the side surface of the metal bank layer BN1 and the side surface of the insulating bank layer BN2 may be anisotropically etched.

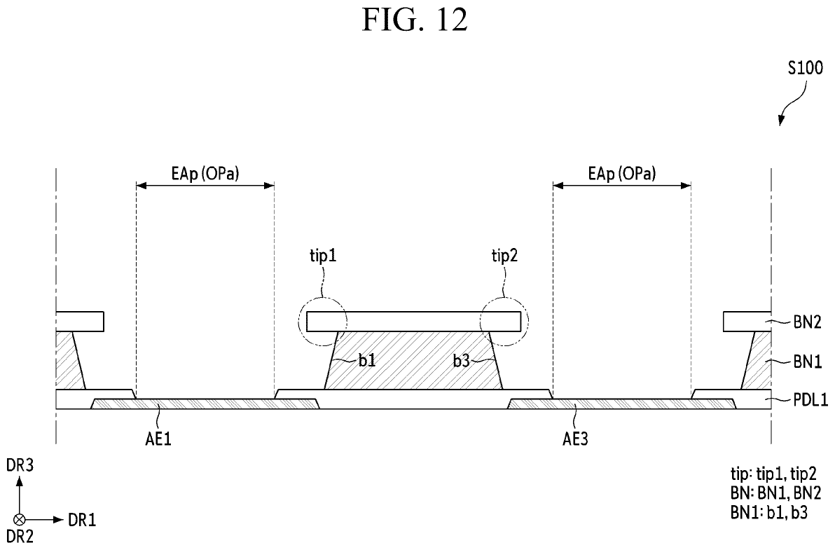

Specifically, referring to FIG. 12, for the same wet etching solution, the metal bank layer BN1 may have a higher etching rate than the insulating bank layer BN2. Accordingly, the insulating bank layer BN2 may include a tip which protrudes further in a direction toward the planar area EAp or the first opening OPa than the first side surface b1 and the second side surface b3 of the metal bank layer BN1.

The tip of the insulating bank layer BN2 may include a first tip tip1 positioned in a direction toward the first anode electrode AE1, and a second tip tip2 positioned in a direction toward the third anode electrode AE3.

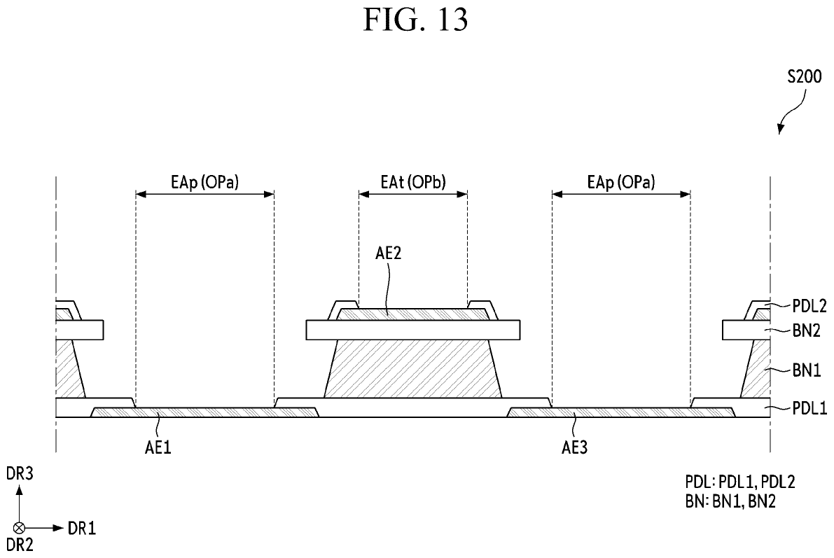

FIG. 13 is a cross-sectional view illustrating process S200 of FIG. 9.

The process (S200) of forming a second anode electrode AE2 on the bank structure BN in a portion overlapping the tower area EAt will be described with reference to FIG. 13. Hereinafter, the pixel defining layer PDL described in process S200 may mean the insulating bank layer BN2 and the second pixel defining layer PDL2.

First, a second anode electrode AE2 is formed on the bank structure BN. The second anode electrode AE2 of a second anode electrode layer may be provided in plural at each of the bank structures BN. The second anode electrode AE2 may overlap the first pixel defining layer PDL1 and the metal bank layer BN1 in a third direction DR3 and may be positioned in contact with the insulating bank layer BN2. Here, anode electrodes of the first anode electrode layer are between the bank structures BN, while anode electrodes of the second anode electrode layer are overlapping the bank structures BN.

In the present process, the second anode electrode AE2 may be positioned at a different height (e.g., in a different plane) from the first anode electrode AE1 and the third anode electrode AE3. In other words, the second anode electrode AE2 may be positioned to be higher in a direction toward one side in the third direction DR3 than the first anode electrode AE1 and the third anode electrode AE3. The second anode electrode AE2 may not overlap the planar area EAp or the first opening OPa.

Next, a second pixel defining layer PDL2 is formed to cover edges of the second anode electrodes AE2. In the present process, the second pixel defining layer PDL2 may be formed through a deposition process and a photo patterning process which form at least one of the aforementioned inorganic insulating materials.

In the present process, the second pixel defining layer PDL2 may define a second opening OPb. The second pixel defining layer PDL2 may expose the second anode electrode AE2 in a portion overlapping the second opening OPb. The second opening OPb may define a tower area EAt.

In an embodiment, all anode electrodes among the first to third light emitting elements ED1, ED2 and ED3 may be provided on the base layer, in respective light emitting areas, before providing any of the light emitting layers or the cathode electrodes of such light emitting elements.

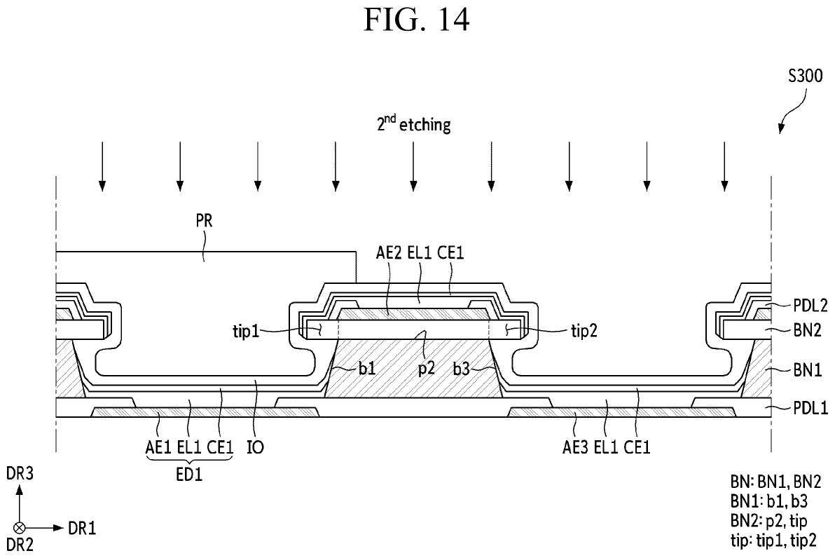

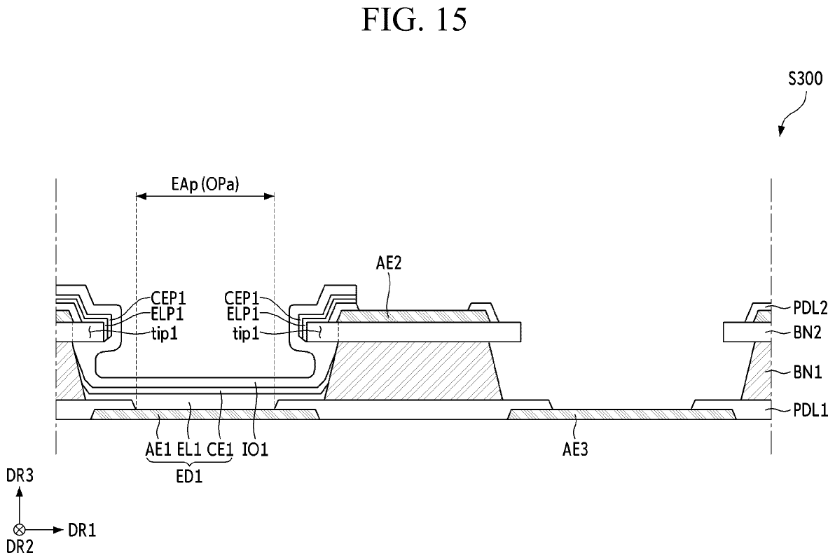

FIGS. 14 and 15 are cross-sectional views illustrating process S300 of FIG. 9.

The process (S300) of forming a first light emitting layer EL1 and a first cathode electrode CE1 on the first anode electrode AE1 in a portion overlapping the planar area EAp will be described with reference to FIGS. 14 and 15.

First, a first light emitting material of a first light emitting layer EL1 is formed on the first anode electrode AE1. The first light emitting layer EL1 may include at least one of blue light and red light. That is, the first light emitting layer EL1 in FIGS. 14 and 15 may represent a planar area light emitting layer which is adjacent to a tower light emitting layer.

In the present process, the process of forming the first light emitting material of the first light emitting layer EL1 may be performed over the entire surface through a deposition process without using a separate fine metal mask.

In an embodiment, the process of forming the first light emitting material of the first light emitting layer EL1 may be performed while the application of the material is inclined at a first angle from an upper surface of the first anode electrode AE1. The first angle described above may be used in the same meaning as a deposition incidence angle. As an example, the first angle may have a range of about 45 degrees or more and about 50 degrees or less. Accordingly, the material forming the first light emitting layer EL1 may be formed on the second anode electrode AE2, the third anode electrode AE3, and the first side surface b1 and the second side surface b3 of the metal bank layer BN1, in addition to the first anode electrode AE1.

However, the material forming the first light emitting layer EL1 formed on each of the first anode electrode AE1, the second anode electrode AE2, and the third anode electrode AE3 may be spaced apart from each other without being connected to each other, as the insulating bank layer BN2 includes the tip. Here, the material is disconnected by the overhanging structure of the tips, to provide first light emitting material patterns both on the bank structures BN and between the bank structures BN.

In the present process, the material forming the first light emitting layer EL1 may also be formed on end surfaces of the first tip tip1 and the second tip tip2 of the insulating bank layer BN2. It is illustrated in the drawings that the material forming the first light emitting layer EL1 is not in contact with a lower surface p2 of the insulating bank layer BN2 which is exposed to the first opening OPa, but in some embodiments, the material forming the first light emitting layer EL1 may also be in contact with a portion of the lower surface p2 of the insulating bank layer BN2. The redundant descriptions will be omitted.

Next, a first cathode electrode CE1 is formed on the first light emitting layer EL1.

In the present process, the process of forming the first cathode electrode material of the first cathode electrode CE1 may be performed over an entire surface through a thermal deposition process or a sputtering process without using a separate fine metal mask. The process of forming the first cathode electrode CE1 may have higher step coverage than the process of forming the first light emitting layer EL1.

In an embodiment, the process of forming the first cathode electrode material of the first cathode electrode CE1 may be performed while the material is applied inclined at a second angle from the upper surface of the first anode electrode AE1. The second angle described above may be used in the same meaning as a deposition incidence angle. As an example, the second angle may be about 30 degrees or less. Accordingly, the material forming the first cathode electrode CE1 may be formed on the second anode electrode AE2, the third anode electrode AE3, and the metal bank layer BN1 in addition to the first anode electrode AE1. In addition, the material forming the first cathode electrode CE1 may be formed on the second anode electrode AE2, the third anode electrode AE3, and the first side surface b1 and the second side surface b3 of the metal bank layer BN1, in addition to the first anode electrode AE1.

However, the material forming the first cathode electrode CE1 formed on each of the first anode electrode AE1, the second anode electrode AE2, and the third anode electrode AE3 may be spaced apart from each other without being connected to each other, as the insulating bank layer BN2 includes the tip. Here, the material is disconnected by the overhanging structure of the tips, to provide first cathode electrode material patterns both on the bank structures BN and between the bank structures BN

In the present process, the material forming the first cathode electrode CE1 may be formed on the end surfaces of the first tip tip1 and the second tip tip2 of the insulating bank layer BN2. It is illustrated in the drawing that the material forming the first cathode electrode CE1 is not in contact with the lower surface p2 of the insulating bank layer BN2, but in some embodiments, the material forming the first cathode electrode CE1 may also be in contact with a portion of the lower surface p2 of the insulating bank layer BN2. The redundant descriptions will be omitted.

Next, an element inorganic layer IO is formed on the first cathode electrode CE1. In the present process, the element inorganic layer IO may be formed by a chemical evaporation deposition (CVD) process. The element inorganic layer IO may have high step coverage characteristics and may be formed with a uniform thickness along the profile of the substructure. In the present process, the element inorganic layer IO may entirely cover the lower structure without any separated portion.

Next, a photoresist PR is formed on the element inorganic layer IO, and a second etching process is performed using the photoresist PR as a mask. The photoresist PR may be formed to cover the first anode electrode AE1 and the second pixel defining layer PDL2 adjacent to the first anode electrode AE1. That is, the photoresist PR overlaps an area corresponding to the first light emitting element ED1, while exposing the stacked structure at a remaining area.

In the present process, the material forming the first light emitting layer EL1, the material forming the first cathode electrode CE1, and the material forming the element inorganic layer IO which do not overlap the photoresist PR may be removed all at once. Here, the layers of the first light emitting element ED1 remain while layers of the remaining area are removed.

As illustrated in FIG. 15, through the present process, the second anode electrode AE2 and the third anode electrode AE3 may be exposed again, and the element inorganic layer IO may be formed in the form of a first element inorganic layer IO1. In this way, the first light emitting element ED1 and the first element inorganic layer IO1 positioned in a portion overlapping the planar area EAp or the first opening OPa may be formed between bank structures BN.

In the present process, the material forming the first light emitting layer EL1 positioned on the first tip tip1 of the insulating bank layer BN2 may be formed in the form of a first organic pattern ELP1. As described above, the first organic pattern ELP1 may be positioned to be spaced apart from the first light emitting layer EL1 and may include the same material as the first light emitting layer EL1.

In the present process, the material forming the first cathode electrode CE1 positioned on the first organic pattern ELP1 in a portion overlapping the first tip tip1 of the insulating bank layer BN2 may be formed in the form of a first electrode pattern CEP1. As described above, the first electrode pattern CEP1 may be positioned to be spaced apart from the first cathode electrode CE1 and may include the same material as the first cathode electrode CE1.

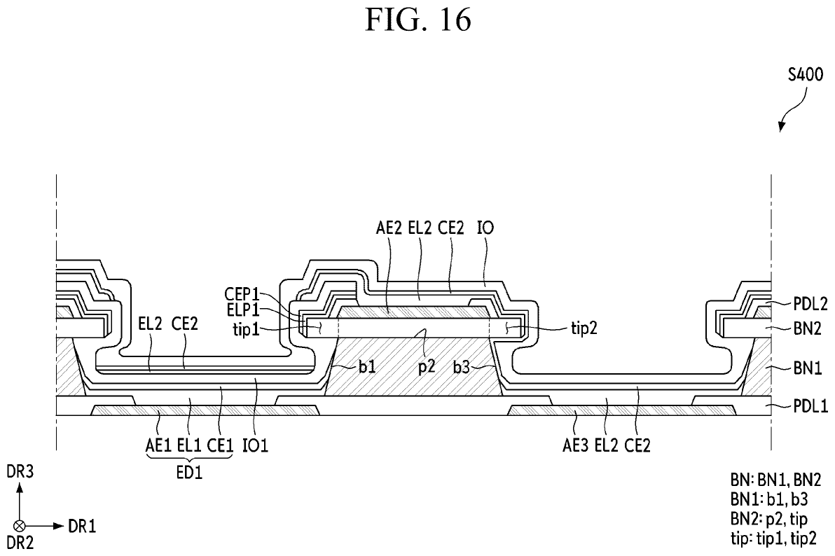

FIGS. 16 to 18 are cross-sectional views illustrating process S400 of FIG. 9.

The process (S400) of forming a second light emitting layer EL2 and a second cathode electrode CE2 on the second anode electrode AE2 in the portion overlapping the tower area EAt will be described with reference to FIGS. 16 to 18.

First, a second light emitting layer EL2 is formed on the second anode electrode AE2. As described above, the second light emitting layer EL2 may include green light.

In the present process, the process of forming a second light emitting material layer of the second light emitting layer EL2 may be performed over the entire surface through a deposition process without using a separate fine metal mask. The process of forming a second light emitting material layer of the second light emitting layer EL2 may be performed as the same process as the process of forming the first light emitting layer EL1. The redundant descriptions will be omitted.

In the present process, the material forming the second light emitting layer EL2 may also be formed on the first element inorganic layer IO1, the second side surface b3 of the metal bank layer BN1, and the third anode electrode AE3, in addition to the second anode electrode AE2.

In the present process, the material forming the second light emitting layer EL2 formed on the first element inorganic layer IO1, the second side surface b3 of the metal bank layer BN1, and the third anode electrode AE3 may be spaced apart from each other without being connected to each other, as the insulating bank layer BN2 includes the tip.

In the present process, the material forming the second light emitting layer EL2 may also be formed on end surfaces the first tip tip1 and the second tip tip2 of the insulating bank layer BN2. In a portion overlapping the first tip tip1, the material forming the second light emitting layer EL2 may overlap the first organic pattern ELP1 and the first electrode pattern CEP1 in the third direction DR3. In a portion overlapping the second tip tip2, the material forming the second light emitting layer EL2 may be in contact with the second pixel defining layer PDL2 and the insulating bank layer BN2. In the portion overlapping the second tip tip2, the material forming the second light emitting layer EL2 may not overlap the first organic pattern ELP1 and the first electrode pattern CEP1 in the third direction DR3.

It is illustrated in the drawing that the material forming the second light emitting layer EL2 is not in contact with the lower surface p2 of the insulating bank layer BN2, but the present disclosure is not limited thereto. According to embodiments, the material forming the second light emitting layer EL2 may also be in contact with a portion of the lower surface p2 of the insulating bank layer BN2 in the portion overlapping the second tip tip2.

As described above, the display device 10 according to an embodiment may solve defects in light emitting reliability caused during the fabricating process by forming the second light emitting layer EL2 to be positioned on the tip of the insulating bank layer BN2. The redundant descriptions will be omitted.

Next, a second cathode electrode CE2 is formed on the second light emitting layer EL2.

In the present process, the process of forming the second cathode electrode material layer of the second cathode electrode CE2 may be performed over an entire surface through a thermal deposition process or a sputtering process without using a separate fine metal mask. The process of forming the second cathode electrode material layer of the second cathode electrode CE2 may have higher step coverage than the process of forming the first cathode electrode CE1.

In the present process, the material forming the second cathode electrode CE2 may also be formed on the first element inorganic layer IO1, the second side surface b3 of the metal bank layer BN1, and the third anode electrode AE3, in addition to the second anode electrode AE2.

In the present process, the material forming the second cathode electrode CE2 may be formed on end surfaces of the first tip tip1 and the second tip tip2 of the insulating bank layer BN2. In a portion overlapping the first tip tip1, the material forming the second cathode electrode CE2 may overlap the first organic pattern ELP1 and the first electrode pattern CEP1 in the third direction DR3.

In the present process, the material forming the second cathode electrode CE2 formed on the first element inorganic layer IO1 and the material forming the second cathode electrode CE2 formed on the second anode electrode AE2 may be spaced apart from each other by a step of the first element inorganic layer IO1 covering the first tip tip1.

In the present process, since the material forming the second cathode electrode CE2 has high step coverage characteristics, it may entirely cover the second tip tip2. In addition, the material forming the second cathode electrode CE2 may extend in entirely covering the second tip tip2 and be positioned in contact with the second side surface b3 of the metal bank layer BN1.

In other words, in the present process, the material forming the second cathode electrode CE2 formed on the second anode electrode AE2 and the material forming the second cathode electrode CE2 formed on the third anode electrode AE3 may be connected to each other.

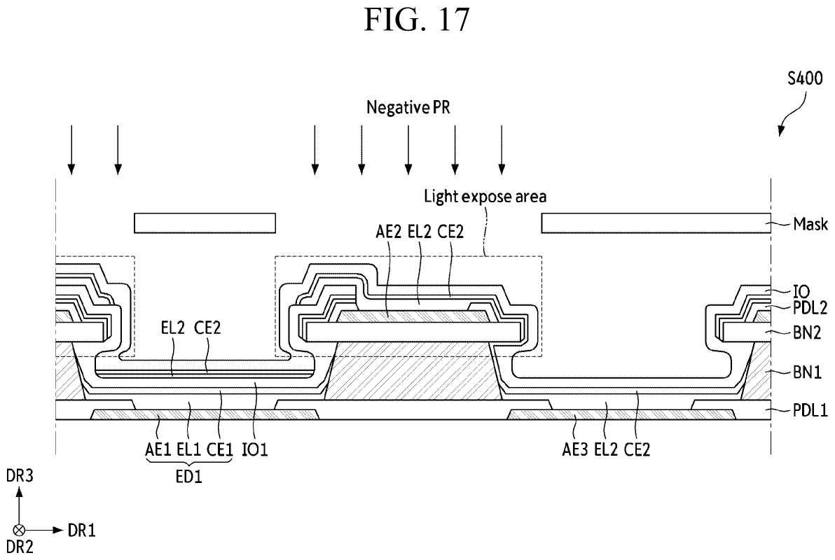

Next, referring to FIG. 17, an element inorganic layer IO is formed on the second cathode electrode CE2. In the present process, the element inorganic layer IO may entirely cover the lower structure without any separated portion. The redundant descriptions will be omitted.

Next, a mask MASK is formed so that the second light emitting layer EL2, the second cathode electrode CE2, and the element inorganic layer IO overlapping the second anode electrode AE2 are exposed. The mask MASK may be positioned in a portion overlapping the first anode electrode AE1 and the third anode electrode AE3.

Next, a negative photoresist (PR) process is performed so that light is provided to a light exposed area.

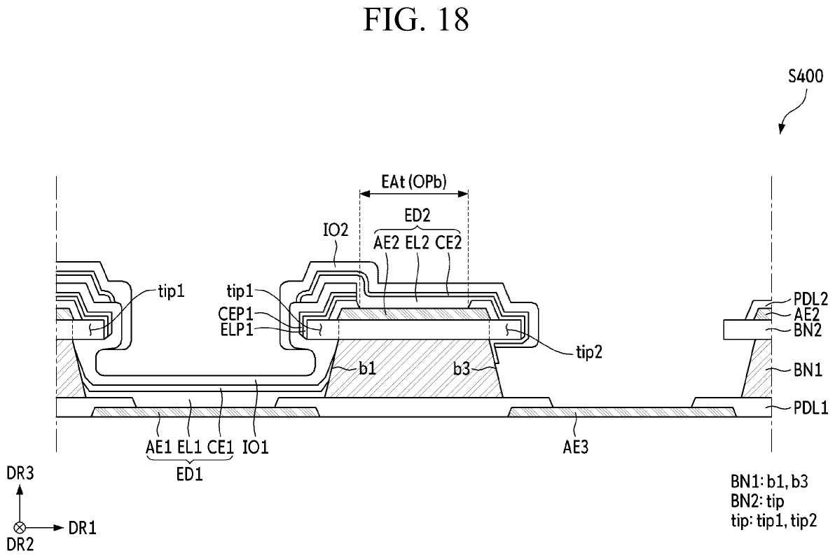

As illustrated in FIG. 18, in the present process, the material forming the second light emitting layer EL2, the material forming the second cathode electrode CE2, and the material forming the element inorganic layer IO which do not overlap the light expose area may be removed all at once.

Through the present process, the first element inorganic layer IO1 and the third anode electrode AE3 may be exposed again, and the element inorganic layer IO may be formed in the form of a second element inorganic layer IO2. In this way, the second light emitting element ED2 and the second element inorganic layer IO2 positioned in a portion overlapping the tower area EAt or the second opening OPb may be formed.

In the present process, the second light emitting layer EL2, the second cathode electrode CE2, and the second element inorganic layer IO2 overlapping the first tip tip1 of the insulating bank layer BN2 may be positioned to overlap the first organic pattern ELP1 and the first electrode pattern CEP1, and the second light emitting layer EL2, the second cathode electrode CE2, and the second element inorganic layer IO2 overlapping the second tip tip2 of the insulating bank layer BN2 may not overlap the first organic pattern ELP1 and the first electrode pattern CEP1.

In the present process, the second cathode electrode CE2 may be positioned partially in contact with the second side surface b3 of the metal bank layer BN1. A portion of the second cathode electrode CE2 positioned on the second side surface b3 of the metal bank layer BN1 may be exposed without being covered by the second element inorganic layer IO2. Accordingly, the second side surface b3 of the metal bank layer BN1 may not be in contact with the second element inorganic layer IO2. As a result, a bonding structure of the first side surface b1 and a bonding structure of the second side surface b3 of the metal bank layer BN1 may be different from each other. The redundant descriptions will be omitted.

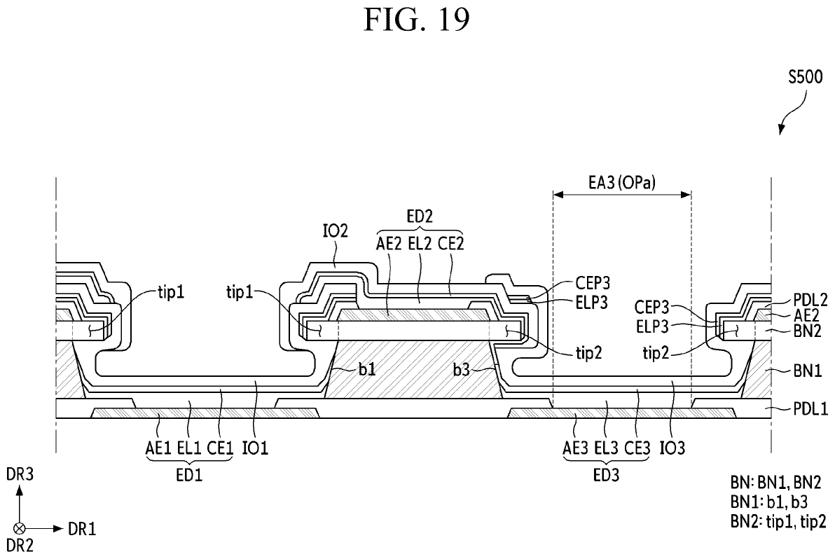

FIG. 19 is a cross-sectional view illustrating process S500 of FIG. 9.

The process (S500) of forming a third light emitting layer EL3 and a third cathode electrode CE3 on the third anode electrode AE3 in the portion overlapping the planar area EAp will be described with reference to FIG. 19 in addition to FIGS. 10 to 18.

Referring to the process of forming the first light emitting element ED1 described above, a third light emitting layer EL3, a third cathode electrode CE3, and a third element inorganic layer IO3 are formed on the third anode electrode AE3.

For example, the process of forming the third light emitting material layer of the third light emitting layer EL3 and the third cathode electrode CE3 may be performed over an entire surface using deposition and photo patterning processes without using a separate fine metal mask. Accordingly, the process of forming the third light emitting material layer of the third light emitting layer EL3 and the third cathode electrode CE3 may be temporarily performed on the first element inorganic layer IO1, the second element inorganic layer IO2, and the second side surface b3 of the metal bank layer BN1.

Thereafter, through an etching process, all the third light emitting material layer is removed except for the third light emitting layer EL3 and the third cathode electrode CE3 positioned on the third anode electrode AE3 and the second pixel defining layer PDL2 adjacent to the third anode electrode AE3.

In the present process, the material forming the third light emitting layer EL3 positioned on the second tip tip2 of the insulating bank layer BN2 and the material forming the third cathode electrode CE3 may be formed in the form of a third organic pattern ELP3 and a third electrode pattern CEP3. As described above, the third organic pattern ELP3 may be positioned to be spaced apart from the third light emitting layer EL3 and may include the same material as the third light emitting layer EL3. In addition, the third electrode pattern CEP3 may be positioned to be spaced apart from the third cathode electrode CE3 and may include the same material as the third cathode electrode CE3.

In the present process, the element inorganic layer IO may be formed in the form of a third element inorganic layer IO3.

In this way, the third light emitting element ED3 and the third element inorganic layer IO3 positioned in a portion overlapping the planar area EAp or the first opening OPa may be formed.

In the display device 10 according to an embodiment, the deposition order of the first to third light emitting elements ED1, ED2, and ED3 may be determined through the order of the element inorganic layers IO stacked on the first tip tip1 and the second tip tip2 of the insulating bank layer BN2. A light emitting structure may include not only the two electrodes with the light emitting layer therebetween of a light emitting element, but also the respective element inorganic layer pattern (e.g., IO1, IO2 or IO3) on such light emitting element.

For example, through the form in which the second element inorganic layer IO2 is positioned on the first element inorganic layer IO1 in the portion overlapping the first tip tip1, it may be seen that the first light emitting element ED1 is first formed and then the second light emitting element ED2 is formed. In addition, through the form in which the third element inorganic layer IO3 is positioned on the second element inorganic layer IO2 in the portion overlapping the second tip tip2, it may be seen that the second light emitting element ED2 is formed and then the third light emitting element ED3 is formed.

As a result, the display element layer EML illustrated in FIG. 5 may be formed.

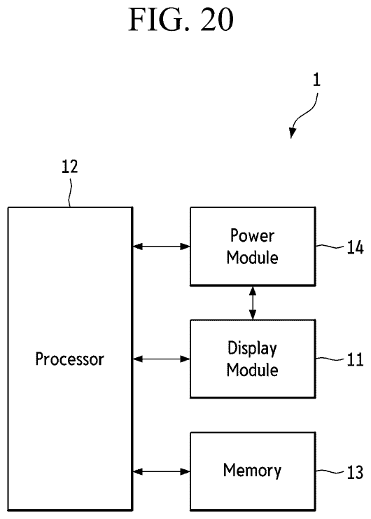

FIG. 20 is a block diagram of an electronic device 1 according to an embodiment.

Referring to FIG. 20, the display device according to the embodiment may be applied to various electronic devices or electronic display devices. An electronic device 1 according to an embodiment may include one or more of the embodiments of the display device 10 described above, and may further include a module or device having additional functions in addition to the display device.

An electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module which converts power supplied by the power supply module to generate power required for an operation of the electronic device 1.

At least one of the components of the electronic device 1 described above may be included in the display device 10 according to the above-described embodiments. In addition, some of the individual modules functionally included within one module may be included within the display device 10, while others may be provided separately from the display device 10. For example, the display device 10 includes the display module 11, and the processor 12, the memory 13 and the power module 14 may be provided in the form of other devices within the electronic device 1 other than the display device 10.

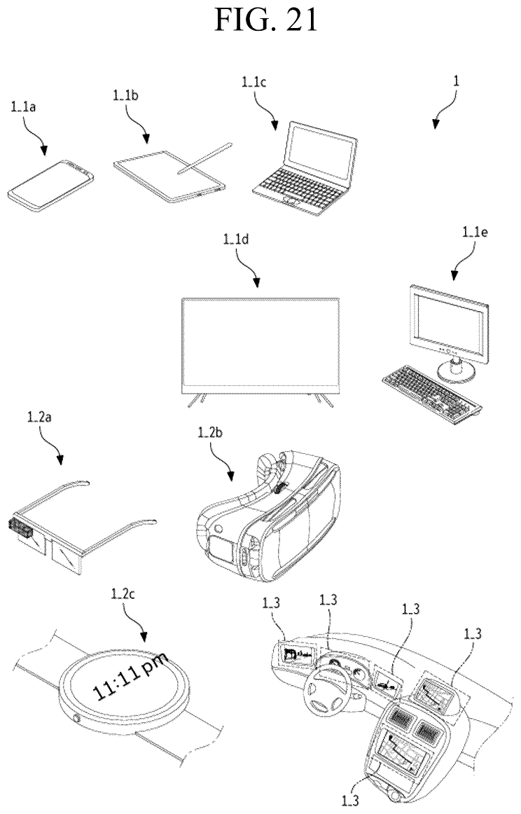

FIG. 21 is a schematic diagram of electronic devices according to various embodiments.

Referring to FIG. 21, various electronic devices 1 to which the display device 10 according to the embodiments is applied may include not only an image display electronic device such as a smart phone 1_1a, a tablet PC 1_1b, a laptop 1_1c, a television (TV) 1_1d, and a desk monitor 1_1e, but also a wearable electronic device including a display module such as a smart glasses 1_2a, a head mounted display 1_2b, a smart watch 1_2c, and the like, and a vehicle electronic device 1_3 including a display module such as a Center Information Display (CID), a room mirror display, etc., disposed on a vehicle's instrument panel, center fascia, or dashboard.

Referring again to FIGS. 1 to 21, in the display device 10 according to an embodiment, the light emitting area EA may be efficiently disposed by disposing the first light emitting element ED1 positioned in the portion overlapping the planar area EAp, the second light emitting element ED2 positioned in the portion overlapping the tower area EAt, and the third light emitting element ED3 positioned in the portion overlapping the planar area EAp to be cross-repeated. Accordingly, the display device 10 according to an embodiment may be applied to an ultra-high resolution electronic device 1 having high pixel integration.

In addition, the display device 10 according to an embodiment may solve defects in light emitting reliability by disposing the second light emitting element ED2 having a relatively narrow width in the portion overlapping the tower area EAt, that is, above the bank structure BN. The redundant descriptions will be omitted.

In an embodiment, the display device 10 includes bank structures BN which are on the substrate SUB, spaced apart from each other and defining a first light emitting area EA1 among the light emitting areas which is between the bank structures BN, a first light emitting element ED1 in the first light emitting area EA1, the first light emitting element ED1 including a first anode electrode AE1, a first light emitting layer EL1 and a first cathode electrode CE1, a first pixel defining layer PDL1 in which a first opening Opa corresponding to the first light emitting area EA1 is defined, the first pixel defining layer PDL1 covering an edge of the first anode electrode AE1, a second pixel defining layer PDL2 which overlaps a bank structure BN among the bank structures BN and in which a second opening OPb is defined, the second opening OPb defining a second light emitting area EA2 among the light emitting areas which overlaps the bank structure BN, and a second light emitting element ED2 in the second light emitting area EA2 and overlapping the bank structure BN, the second light emitting element ED2 including a second anode electrode AE2 having an edge covered by the second pixel defining layer PDL2, a second light emitting layer EL2 and a second cathode electrode CE2.

The second anode electrode AE2 may be further from the substrate SUB than the first anode electrode AE1 in a direction perpendicular to the substrate SUB (e.g., the third direction DR3 or the thickness direction.) Similarly, the second cathode electrode CE2 may be further from the substrate SUB than the first cathode electrode CE1 in a direction perpendicular to the substrate SUB.

A planar area of the first light emitting area EA1 may be defined by a planar area of the first opening OPa, a planar area of the second light emitting area EA2 may be defined by a planar area the second opening OPb, and the planar area of the first light emitting area EA1 which is between the bank structures BN may be greater than the planar area of the second light emitting area EA2 which overlaps the bank structure BN.

The bank structure may include a metal bank layer BN1 including a first side surface b1 closest to the first light emitting area EA1, and an insulating bank layer BN2 (e.g., an inorganic insulating bank layer) on the metal bank layer BN1 and having a tip which protrudes further than the first side surface b1 of the metal layer BN1 and toward the first light emitting area EA1. Here, the metal bank layer may further include the first side surface b1 in contact with the first cathode electrode CE1, and a second side surface b3 which is opposite to the first side surface b1 and in contact with the second cathode electrode CE2. The first cathode electrode CE1 and the second cathode electrode CE2 may be electrically connected to each other by the metal bank layer BN1.

The display device 10 may further include a third light emitting area EA3 among the light emitting areas which is defined between the bank structures BN, the first light emitting area EA1, the second light emitting area EA2 and the third light emitting area EA3 consecutively arranged along the substrate SUB, and a third light emitting element ED3 which is in the third light emitting area EA3 and spaced apart from the first light emitting element ED1 with the bank structure BN therebetween, the third light emitting element ED3 including a third cathode electrode CE3 in contact with the second side surface b3 of the metal bank layer BN1. The first light emitting element ED1 and the third light emitting element ED3 may be coplanar with each other.

In the first light emitting area EA1 and the third light emitting area EA3 which are defined between the bank structures BN, the first light emitting element ED1 and the third light emitting element ED3 emit at least one of blue light and red light, and in the second light emitting area EA2 which overlaps the bank structure BN, the second light emitting element ED2 emits green light.

In an embodiment of a method for providing a display device 10, the method include providing a first anode electrode AE1 of a first light emitting element ED1 in a first light emitting area EA1 of a substrate SUB, providing a bank structure BN in a second light emitting area EA2 of the substrate SUB, the bank structure BN being adjacent to the first light emitting area EA1 in a direction along the substrate SUB, providing a second anode electrode AE2 of a second light emitting element ED2 which overlaps the bank structure BN in the second light emitting area EA2, and after the providing both of the first anode electrode and the second anode electrode providing a first light emitting layer EL1 and a first cathode electrode CE1 of the first light emitting element ED1, on the first anode electrode AE1, and providing a second light emitting layer EL2 and a second cathode electrode CE2 of the second light emitting element ED2, on the second anode electrode AE2 and overlapping the bank structure BN.

Embodiments of the disclosure should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including light emitting areas;
bank structures which are on the substrate, spaced apart from each other and defining a first light emitting area among the light emitting areas which is between the bank structures;
a first light emitting element in the first light emitting area, the first light emitting element including a first anode electrode, a first light emitting layer and a first cathode electrode;
a first pixel defining layer in which a first opening corresponding to the first light emitting area is defined, the first pixel defining layer covering an edge of the first anode electrode;
a second pixel defining layer which overlaps a bank structure among the bank structures and in which a second opening is defined, the second opening defining a second light emitting area among the light emitting areas which overlaps the bank structure; and
a second light emitting element in the second light emitting area and overlapping the bank structure, the second light emitting element including a second anode electrode having an edge covered by the second pixel defining layer, a second light emitting layer and a second cathode electrode.

2. The display device of claim 1, wherein the second anode electrode is further from the substrate than the first anode electrode in a direction perpendicular to the substrate.

3. The display device of claim 2, wherein
a planar area of the first light emitting area is defined by a planar area of the first opening,
a planar area of the second light emitting area is defined by a planar area the second opening, and
the planar area of the first light emitting area which is between the bank structures is greater than the planar area of the second light emitting area which overlaps the bank structure.

4. The display device of claim 1, wherein the bank structure includes:
a metal bank layer including a first side surface closest to the first light emitting area, and
an insulating bank layer on the metal bank layer and having a tip which protrudes further than the first side surface of the metal layer and toward the first light emitting area.

5. The display device of claim 4, wherein the second cathode electrode is further from the substrate than the first cathode electrode in a direction perpendicular to the substrate.

6. The display device of claim 4, wherein the metal bank layer further includes:
the first side surface in contact with the first cathode electrode; and
a second side surface which is opposite to the first side surface and in contact with the second cathode electrode, and
the first cathode electrode and the second cathode electrode are electrically connected to each other by the metal bank layer.

7. The display device of claim 6, wherein
the first light emitting layer is in contact with the first side surface of the metal bank layer, and
the second light emitting layer is not in contact with the metal bank layer.

8. The display device of claim 6, further comprising:
a third light emitting area among the light emitting areas which is defined between the bank structures, the first light emitting area,
the second light emitting area and the third light emitting area consecutively arranged along the substrate, and
a third light emitting element which is in the third light emitting area and spaced apart from the first light emitting element with the bank structure therebetween, the third light emitting element including a third cathode electrode in contact with the second side surface of the metal bank layer,
wherein the first light emitting element and the third light emitting element are coplanar with each other.

9. The display device of claim 8, wherein
the first side surface of the metal bank layer includes:
a first portion in contact with the first light emitting layer, and
a second portion in contact with the first cathode electrode, and
the second side surface of the metal bank layer includes:
a first portion in contact with the third cathode electrode, and
a second portion in contact with the second cathode electrode.

10. The display device of claim 8, wherein
the first light emitting element, the second light emitting element and the third light emitting element emit different light colors,
in the first light emitting area and the third light emitting area which are defined between the bank structures, the first light emitting element and the third light emitting element emit at least one of blue light and red light, and
in the second light emitting area which overlaps the bank structure, the second light emitting element emits green light.

11. A method for providing a display device, the method comprising:
providing a first anode electrode of a first light emitting element in a first light emitting area of a substrate;
providing a bank structure in a second light emitting area of the substrate, the bank structure being adjacent to the first light emitting area in a direction along the substrate;
providing a second anode electrode of a second light emitting element which overlaps the bank structure in the second light emitting area; and
after the providing of the first anode electrode and the second anode electrode:
providing a first light emitting layer and a first cathode electrode of the first light emitting element, on the first anode electrode; and
providing a second light emitting layer and a second cathode electrode of the second light emitting element, on the second anode electrode and overlapping the bank structure.

12. The method of claim 11, wherein the bank structure includes:
a metal bank layer including a first side surface closest to the first light emitting area, and
an inorganic insulating bank layer on the metal bank layer and having a tip which protrudes further than the first side surface of the metal layer and toward the first light emitting area.

13. The method of claim 12, wherein in the providing of the second anode electrode on the bank structure, the second anode electrode is further from the substrate than the first anode electrode in a direction perpendicular to the substrate.

14. The method of claim 11, wherein the first light emitting layer, the first cathode electrode, the second light emitting layer and the second cathode electrode are provided by a deposition process and a photo patterning process without using a separate fine metal mask.

15. An electronic device comprising:
a display device including light emitting areas arranged spaced apart from each other along a substrate; and
a display module, a processor, a memory or a power module which is connected to the display device,
wherein the display device includes:
bank structures which are on the substrate, spaced apart from each other and defining a first light emitting area among the light emitting areas which is between the bank structures;
a first light emitting element in the first light emitting area, the first light emitting element including a first anode electrode, a first light emitting layer and a first cathode electrode;
a first pixel defining layer in which a first opening corresponding to the first light emitting area is defined, the first pixel defining layer covering an edge of the first anode electrode;
a second pixel defining layer which overlaps a bank structure among the bank structures and in which a second opening is defined, the second opening defining a second light emitting area among the light emitting areas which overlaps the bank structure; and
a second light emitting element in the second light emitting area and overlapping the bank structure, the second light emitting element including a second anode electrode having an edge covered by the second pixel defining layer, a second light emitting layer and a second cathode electrode.

16. The electronic device of claim 15, wherein the second anode electrode is further from the substrate than the first anode electrode in a direction perpendicular to the substrate.

17. The electronic device of claim 16, wherein
a planar area of the first light emitting area is defined by a planar area of the first opening,
a planar area of the second light emitting area is defined by a planar area the second opening, and
the planar area of the first light emitting area which is between the bank structures is greater than the planar area of the second light emitting area which overlaps the bank structure.

18. The electronic device of claim 15, wherein the bank structure includes:
a metal bank layer including a first side surface closest to the first light emitting area, and
an insulating bank layer on the metal bank layer and having a tip which protrudes further than the first side surface of the metal layer and toward the first light emitting area.

19. The electronic device of claim 18, wherein the second cathode electrode is further from the substrate than the first cathode electrode in a direction perpendicular to the substrate.

20. The electronic device of claim 19, wherein
the metal bank layer further includes:
the first side surface in contact with the first cathode electrode; and
a second side surface which is opposite to the first side surface and in contact with the second cathode electrode, and
the first cathode electrode and the second cathode electrode are electrically connected to each other by the metal bank layer.
